(19) United States
(12) Patent Application Publication
(10) Pub. No.: US 2021/0149111 A1
(43) Pub. Date: May 20, 2021

(54) OPTICAL MULTIPLEXER, LIGHT SOURCE MODULE, TWO-DIMENSIONAL OPTICAL SCANNING DEVICE, AND IMAGE PROJECTION DEVICE

(71) Applicant: University of Fukui, Fukui-shi (JP)

(72) Inventors: Toshio Katsuyama, Fukui-shi (JP); Shoji Yamada, Fukui-shi (JP)

(73) Assignee: University of Fukui, Fukui-shi (JP)

(21) Appl. No.: 17/159,643

(22) Filed: Jan. 27, 2021

Related U.S. Application Data
(63) Continuation of application No. PCT/JP2019/003660, filed on Feb. 1, 2019.

(30) Foreign Application Priority Data
Oct. 18, 2018 (JP) 2018-196990

(51) Int. Cl. G02B 6/12; G02B 26/10; G02B 26/08; G02B 6/125; G03B 21/20

(52) U.S. Cl. CPC G02B 6/12007; G02B 26/101; G03B 21/2033; G02B 6/125; G03B 21/2013; G02B 26/0816

(57) ABSTRACT

The invention relates to an optical multiplexer, a light source module, a two-dimensional optical scanning device and an image projection device, where the effects of stray light that has failed to enter into an input optical waveguide can be reduced. Light that is in or below the range of 2.5 times greater than the full width at half maximum of the light intensity distribution of a light beam that has not been inputted into an optical waveguide from among the respective light beams that have been inputted into the input ends of the plurality of input optical waveguides is prevented from overlapping with the multiplexed light outputted from the output optical waveguide in the output end of the output optical waveguide.

### CROSS REFERENCE TO RELATED APPLICATIONS

This application is a continuation of International Application No. PCT/JP2019/003660, filed on Feb. 1, 2019, now pending, herein incorporated by reference. Further, this application is based upon and claims the benefit of priority from the prior Japanese Patent Application No. 2018-196990, filed on Oct. 18, 2018, the entire contents of which are incorporated herein by reference.

### FIELD

The present invention relates to an optical multiplexer, a light source module, a two-dimensional optical scanning device and an image projection device, and relates to, for example, the configuration for reducing the effects of stray light from a light source on the multiplexed output from an optical multiplexer.

### BACKGROUND

Various forms of light beam multiplexing light sources have been known as conventional devices for multiplexing a plurality of light beams such as laser beams so as to radiate one light beam. From among these, light beam multiplexing light sources where semiconductor lasers and optical waveguide-type optical multiplexers are combined are characterized in that the device can be made compact and the power can be lowered, and thus are applied to a laser beam scanning-type color image projection device (see Patent Literature 1 through 6).

Conventional light beam multiplexing light sources where semiconductor lasers and optical waveguide-type optical multiplexers are combined include a light beam multiplexing light source for multiplexing laser beams of three primary colors as illustrated in Patent Literature 3, for example. As illustrated in FIGS. 3 and 10 in Patent Literature 3, a light beam multiplexing light source is formed of optical waveguides made of a core and a clad, and semiconductor lasers for generating light beams of red, blue and green are installed along the input ends of the optical waveguides that correspond to the respective colors. Here, the light beams propagate through the cores of the optical waveguides and are emitted from the output end of an optical multiplexer as a multiplexed light beam.

FIG. 20 is a schematic diagram illustrating a two-dimensional optical scanning device that has been proposed by the present inventors (see Patent Literature 6). An optical multiplexer 62 is provided on a substrate 61 on which a movable mirror unit 63 is formed, and a blue semiconductor laser chip 32, a green semiconductor laser chip 33 and a red semiconductor laser chip 34 are coupled with the optical multiplexer 62. Even in the case where the two-dimensional optical scanning device is integrated with the light sources for generating light beams, the total size after the integration can be made small because the movable mirror unit 10 is made compact. In particular, in the case where the light sources for emitting light beams are semiconductor laser chips or optical multiplexers, these semiconductor laser chips or optical multiplexers can be formed on an Si substrate or a metal plate substrate, and therefore, such effects can be gained where the entire size after integration can be made small when the light sources and the two-dimensional optical scanning mirror device are formed on such a substrate.

FIG. 21 is a schematic diagram illustrating an image projection device that has been proposed by the present inventors (see Patent Literature 6). A two-dimensional scanning device as described above, a two-dimensional scanning control unit for two-dimensional scanning with emission light that has been emitted from a light source by applying a two-dimensional optical scanning signal to an electromagnetic coil 64, and an image formation unit for projecting onto a projection plane an image scanned with the emission light are combined. Here, a typical example of the image projection device is an eyeglass-type retina scanning display.

In this case, the entirety of the light beams that have been emitted from the semiconductor lasers for the respective colors is not guided into the core due to the difference in the form of the light beams emitted from the semiconductor lasers and the form of the cores, and part of the light beams leaks into a clad portion. Conventionally it has been said that the leaked light disseminates while progressing through the inside of an optical multiplexer or is radiated to the outside so as to be reduced to a neglectable degree.

### CITATION LIST

### Patent Literature

Patent Literature 1: Japanese Unexamined Patent Publication 2008-242207
Patent Literature 2: Japanese Unexamined Patent Publication 2016-012042
Patent Literature 3: Japanese Unexamined Patent Publication 2010-049259
Patent Literature 4: Japanese Unexamined Patent Publication 2013-195603
Patent Literature 5: U.S. Unexamined Patent Publication 2010/0073262
Patent Literature 6: Japanese Unexamined Patent Publication 2018-072591

### Non-Patent Literature

Non-Patent Literature 1: IEEE Photonics Technology Letters, vol. 19, no. 5, pp. 330-332, Mar. 1, 2007

### SUMMARY

It has become clear in the optical waveguide-type optical multiplexer that was diligently examined by the present inventors that the effects of the light that has leaked to a clad portion as described above cannot be neglected as compared to the light beam that has been multiplexed in the optical multiplexing unit. Part of the light that has leaked into a clad portion propagates through the clad portion at a certain efficiency, and therefore, the light that has failed to be guided into the core so as to propagate through a clad portion propagates up to an end surface of the optical multiplexer, particularly in the case where the optical multiplexer is small.

Such a light propagation through a clad portion is different from the propagation through the total reflections from the interface between the core layer and the clad layer, and is considered to be a propagation through reflections from the surface of the clad layer or the interface between the clad layer and the substrate even though the efficiency thereof is poor, and thus, this situation is described below in reference to FIG. 22.

FIG. 22 is a diagram illustrating a problem with a conventional light source module. A light beam that propagates through a clad portion made of a lower clad layer and an upper clad layer without being guided into any of the core layers of the input optical waveguides 23 through 25, that is to say, part of a clad mode light 51, reaches the output end 29 of the optical multiplexing unit 27 and its proximity. As a result, part of the clad mode light 51 that has propagated through the clad portion becomes noise light 52, which then is multiplexed with and added to the multiplexed output light 50 that has propagated through the core layer. In the case where a lens 49 such as a condenser lens or a sphere lens at an end of an optical fiber is installed at the output end for emitting a light beam, for example, such a problem arises that it becomes difficult to allow only multiplexed output light 50 to be emitted.

In the case of a conventional optical multiplexer having a problem as described above, the size thereof is relatively large, and therefore, the light beam that has failed to enter into the core layer from a light source has a small effect as stray light. As a result of diligent research by the present inventors, however, it was found for the first time that the effects of the stray light might cause a problem due to the miniaturization of the optical multiplexer.

In the case where the optical waveguide in the middle of the optical multiplexer is linear as illustrated in FIG. 22, the multiplexed light beam to be emitted from the output end is in particular, negatively affected. FIG. 23 is a diagram illustrating the spreading of the clad mode light in the lateral direction in a conventional optical multiplexer. Here, one example of the results of measurement of the intensity distribution of a light beam at the output end surface of an optical multiplexer having a length of 9 mm is illustrated. FIG. 23A is a photograph depicting the spreading of the clad mode light, and FIG. 23B is a graph illustrating the intensity distribution of the clad mode light. As is clear from FIG. 23A, how the clad mode light, which is a light beam that has propagated through a clad portion, spreads wide laterally is clearly recognized where it is found that the bright spot at the center is original output multiplexed light that has propagated through the core layer. Here, the center protrusion in FIG. 23B is greatly lower than in reality due to the saturation of the output of the photodetector, and the trenches that appear periodically in the graph are caused by the effects of the mesh on the backdrop when the photograph was taken.

In the case of a retina scanning display in particular, the negative effects as described above, that is to say, the effects of light that has propagated through the clad, cannot be neglected when it is necessary for the intensity of light with which a retina is irradiated to be lowered by approximately two digits relative to the light outputted from the semiconductor laser. As a result, such a problem arises when a light beam scanning-type image is formed by using a light beam emitted from an optical multiplexer that the light that has propagated through a clad portion mixes into the original multiplexed signal light so as to cause a color shift, a color irregularity and the like in the image which deteriorates the quality of the image.

An object of the present invention is to provide an optical multiplexer having input optical waveguides, an output optical waveguide and optical multiplexing units, where the effects of light that has failed to enter into the core layer from among light beams emitted from light sources for emitting light beams into the input ends of the input optical waveguides on the multiplexed output can be reduced.

According to one aspect of the invention, an optical multiplexer is provided with: a plurality of input optical waveguides for individually guiding light beams from a plurality of light sources; an optical multiplexing unit for multiplexing a plurality of light beams from the input optical waveguides; and an output optical waveguide for outputting multiplexed light that has been multiplexed in the optical multiplexing unit, wherein light that is in or below the range of 2.5 times greater than the full width at half maximum of the light intensity distribution of the light beam that has not entered into an input optical waveguide from among the respective light beams that have entered into the input ends of the plurality of input optical waveguides does not overlap with the multiplexed light outputted from the output optical waveguide in the output end of the output optical waveguide.

According to another aspect of the invention, a light source module has an optical multiplexer as described above and a plurality of light sources for entering light beams into the optical multiplexer as described above.

According to still another aspect of the invention, a two-dimensional optical scanning device has a light source module as described above and a two-dimensional optical scanning mirror device for two-dimensional scanning with multiplexed light emitted from the light source module as described above.

According to yet another aspect of the invention, an image projection device has a two-dimensional optical scanning device as described above and an image formation unit for projecting onto a projection plane an image scanned with multiplexed light by means of the two-dimensional optical scanning mirror device as described above.

As one effect of the invention, it becomes possible in an optical multiplexer having input optical waveguides, an output optical waveguide and an optical multiplexing unit to reduce the effects of a light beam that has failed to be inputted into an input optical waveguide from among the light beams that have been emitted from the light sources for emitting light beams into the input ends of the input optical waveguides on the multiplexed output.

### BRIEF DESCRIPTION OF DRAWINGS

FIGS. 1A and 1B are schematic diagrams illustrating the configuration of an optical multiplexer according to an embodiment of the present invention;

FIG. 2 is a diagram illustrating the spread of a beam in the embodiment of the present invention

FIG. 3 is a graph illustrating the range of the spread of a beam in the embodiment of the present invention;

FIGS. 4A, 4B and 4C are diagrams illustrating the structures of optical multiplexing units in the embodiment of the present invention;

FIGS. 5A and 5B are diagrams schematically illustrating the configuration of the optical multiplexer in Example 1 of the present invention;

FIGS. 6A and 6B are diagrams schematically illustrating the configuration of the optical multiplexer in Example 3 of the present invention;

FIGS. 7A and 7B are diagrams schematically illustrating the configuration of the optical multiplexer in Example 4 of the present invention;

FIGS. 8A and 8B are diagrams schematically illustrating the configuration of the optical multiplexer in Example 5 of the present invention;

FIGS. 9A and 9B are diagrams schematically illustrating the configuration of the optical multiplexer in Example 6 of the present invention;

FIGS. 10A and 10B are diagrams schematically illustrating the configuration of the optical multiplexer in Example 7 of the present invention;

FIGS. 11A and 11B are diagrams schematically illustrating the configuration of the optical multiplexer in Example 8 of the present invention;

FIGS. 12A and 12B are diagrams schematically illustrating the configuration of the optical multiplexer in Example 9 of the present invention;

FIG. 13 is a diagram schematically illustrating the configuration of the optical multiplexer in Example 10 of the present invention;

FIG. 14 is a diagram schematically illustrating the configuration of the optical multiplexer in Example 11 of the present invention;

FIG. 15 is a diagram schematically illustrating the configuration of the optical multiplexer in Example 12 of the present invention;

FIG. 16 is a diagram schematically illustrating the configuration of the optical multiplexer in Example 13 of the present invention;

FIG. 17 is a diagram schematically illustrating the configuration of the light source module in Example 14 of the present invention;

FIG. 18 is a diagram schematically illustrating the configuration of the light source module in Example 15 of the present invention;

FIG. 19 is a diagram schematically illustrating the configuration of the light source module in Example 16 of the present invention;

FIG. 20 is a perspective diagram schematically illustrating an example of a conventional two-dimensional optical scanning device;

FIG. 21 is a perspective diagram schematically illustrating a conventional image formation device;

FIG. 22 is a diagram illustrating a problem in a conventional light source module; and

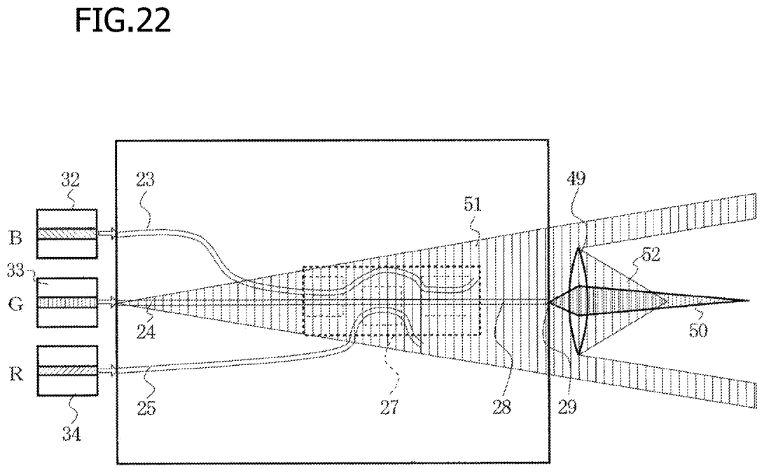

FIGS. 23A and 23B are a photograph and a diagram illustrating the spread of clad mode light in the lateral direction in a conventional optical multiplexer.

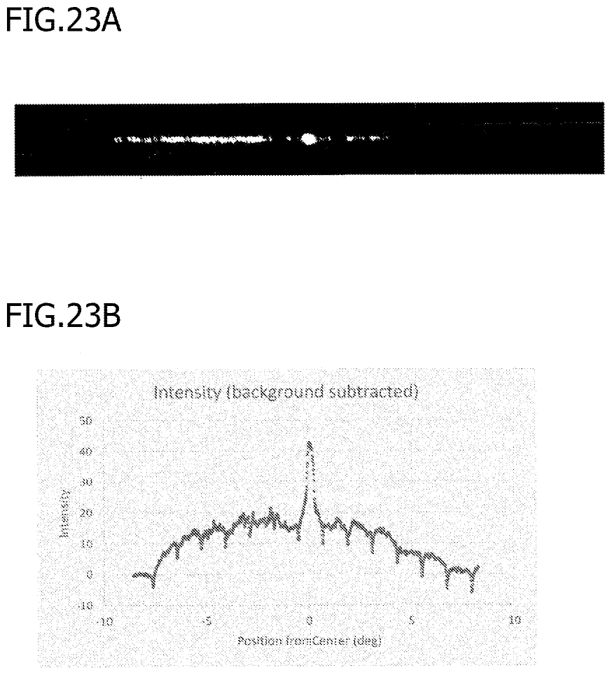

### DESCRIPTION OF EMBODIMENTS

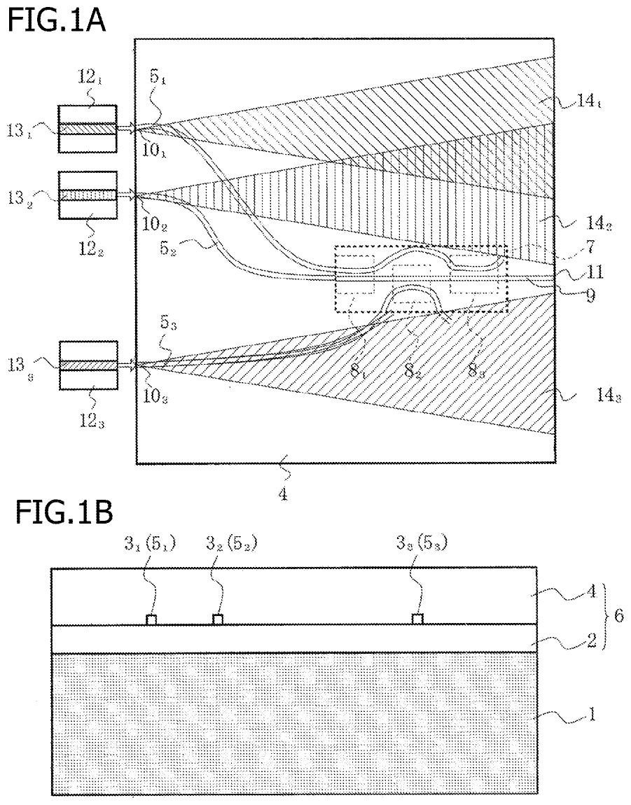

An example of an optical multiplexer according to an embodiment of the present invention is described in reference to FIGS. 1A through 4C. FIGS. 1A and 1B are schematic diagrams illustrating the configuration of the optical multiplexer according to the embodiment of the present invention. FIG. 1A is a plan diagram, and FIG. 1B is a cross-sectional diagram illustrating the end surface on the input end side. Here, the optical multiplexer is described as a light source module by adding light sources 12₁ through 12₃. As illustrated in FIG. 1A, the optical multiplexer according to the embodiment of the present invention is provided with: a plurality of input optical waveguides 5₁ through 5₃ for individually guiding light beams from a plurality of light sources 12₁ through 12₃; an optical multiplexing unit 7 for multiplexing a plurality of light beams from the input optical waveguides 5₁ through 5₃; and an output optical waveguide 9 for outputting multiplexed light that has been multiplexed in the optical multiplexing unit 7. Light that is in or below the range of the light intensity distribution of at least 2.5 times greater than the full width at half maximum of the light beams that have failed to be inputted into the input optical waveguides 5₁ through 5₃ from among the respective light beams to be inputted into the input ends 10₁ through 10₃ of the plurality of input optical waveguides 5₁ through 5₃ is prevented from overlapping with multiplexed light that has been outputted from the output optical waveguide 9 in the output end 11 of the output optical waveguide 9. Here, FIG. 1B is a cross-sectional diagram illustrating the optical multiplexer on the input end side in FIG. 1A. As illustrated in FIG. 1B, the respective optical waveguides are formed by providing core layer 3₁ through 3₃ on a substrate 1 with a lower clad layer 2 in-between, and by providing an upper clad layer 4 so as to cover the core layer 3₁ through 3₃. On the input end side, cores in the core layer 3₁ through 3₃ are surrounded by a clad portion 6 made of the lower clad layer 2 and the upper clad layer, and thus, the input optical waveguides 5₁ through 5₃ are formed. Here, three input optical waveguides 5₁ through 5₃ are illustrated; however, the number of the input optical waveguides is arbitrary and may be two, four or more. Here, ends of the respective optical waveguides in the optical multiplexing unit 7 are not shown, except the one that is connected to the output optical waveguide 9; however, in reality, the ends of the other optical waveguides extend to an end portion of the substrate 1 (the same is applied for the respective drawings showing the following examples).

The light intensity of a light beam that has failed to be inputted into an input optical waveguide 5₁ through 5₃ and that is prevented from overlapping with the multiplexed light that has been outputted from the output optical waveguide 9 depends on the sensitivity/tolerance of a target device. When the light intensity is in a range of full width at half maximum of the light intensity distribution at the output end of each input optical waveguide 5₁ through 5₃, for example, a clear image can be seen in practice. In the case where a higher definition image is required, the light intensity may be in a range from 1.5 times greater than the full width at half maximum so that the multiplexed output with less noise as compared to the case of full width at half maximum can be gained. Furthermore, the light intensity may be in or below a range of 2.5 times greater than the full width at half maximum, in which case multiplexed output with a further less noise as compared to the case where the range is 1.5 times greater than the full width at half maximum can be gained. Here, the light intensity distribution at the output end of each input optical waveguide 5₁ through 5₃ means the light intensity distribution of the spreading in the lateral direction of a light beam that has failed to be inputted into an input optical waveguide 5₁ through 5₃, namely, a light beam that has propagated through the clad, from among the respective input optical waveguides 5₁ through 5₃, that is to say, the intensity distribution that corresponds to the square of the electrical field intensity of the light beam.

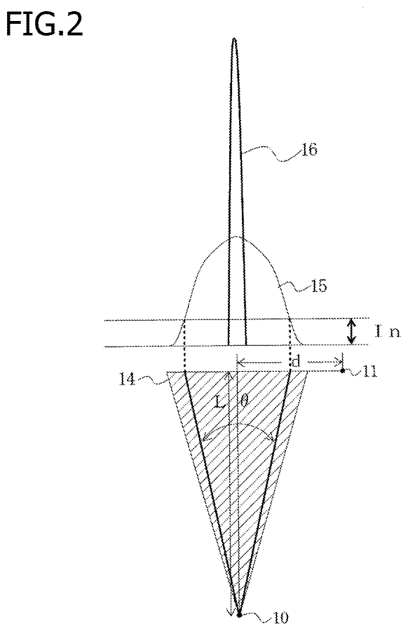

FIG. 2 is a diagram illustrating the spread of a beam in the embodiment of the present invention. The ratio S/N of the light intensity of a light beam signal that is required for the drawing of an image using a light beam to that of the clad mode light, which becomes noise, is found, and then, the beam spread angle θ where the noise light intensity has the lowest value Iₙ that does not satisfy S/N required for the drawing at high definition is found. In the case where the optical multiplexer is used in an image formation device, for example, naturally, it is necessary for the noise light intensity to be sufficiently lower than the light intensity at the minimum gradation when the light intensity of the dots for drawing an image is varied with 256 gradations. Accordingly, the S/N in this case is found from the light intensity that provides this minimum gradation. In FIG. 2, 15 is the distribution of light that has propagated through the clad portion 6, that is to say, the clad mode light distribution, and 16 is a multiplexed output light distribution. When the size of the optical waveguide, that is to say, the distance between the input end 10 and the output end surface is L, it is necessary for the distance d between the center of the clad mode light 14 and the output end 11 of the output optical waveguide to satisfy d>L×tan (θ/2), and the location of the output end 11 of the output optical waveguide (9) is determined relative to the location of the input end 10 so that this value of d is satisfied.

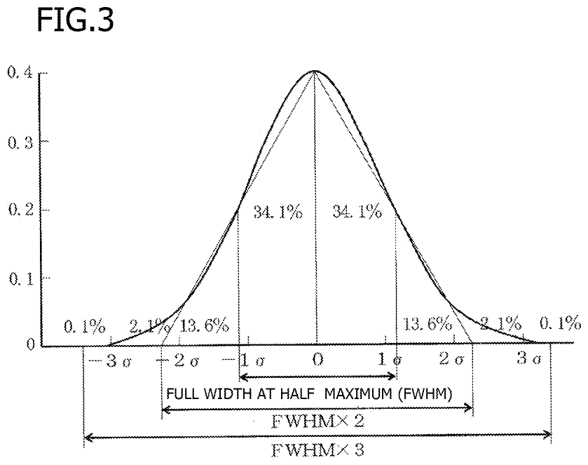

FIG. 3 is a graph illustrating the range of the spread of a beam in the embodiment of the present invention. The clad mode light distribution is described by using a normal distribution (Gaussian Distribution). A clear image can be seen in practice by preventing the light in the range of the full width at half maximum (FWHM) from overlapping with the multiplexed light. In the case where light in the range of 1.5 times greater than the full width at half maximum is prevented from overlapping with the multiplexed light, light of approximately 10% of the light beam becomes noise, and furthermore, in the case where light in the range of 2.5 times greater than the full width at half maximum is prevented from overlapping with the multiplexed light, only light of approximately 0.3% of the light beam becomes noise, and therefore, a higher definition image can be formed.

Typically, the wavelengths of light emitted from a plurality of light sources 12₁ through 12₃ are different from each other as those of the three primary colors, R (red light), G (green light) and B (blue light), and at least two wavelengths from among the wavelengths emitted from the plurality of light sources 12₁ through 12₃ may be the same.

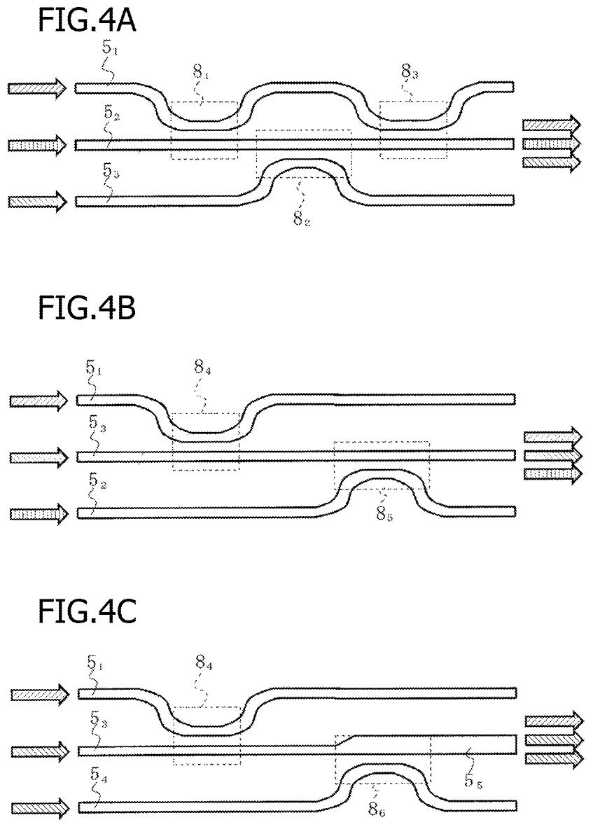

As for the concrete configuration of the optical multiplexing unit 7, as illustrated in FIG. 4A, an optical waveguide 5₃ for guiding red light, an optical waveguide 5₂ for guiding green light and an optical waveguide 5₁ for guiding blue light may be provided in such a manner that the optical waveguide 5₂ that is arranged at the center from among the three optical waveguides 5₁ through 5₃ is an optical waveguide in linear form. Here, the symbols 5₁ through 5₃ for the input optical waveguides are used as the optical waveguides in the optical multiplexing unit.

Concretely, an optical waveguide 5₂ in linear form for guiding green light, an optical waveguide 5₁ for guiding blue light which optically couples with the optical waveguide 5₂ for guiding green light through two optical coupling parts 8₁ and 8₃, and an optical waveguide 5₃ for guiding red light which optically couples with the optical waveguide 5₂ for guiding green light through the portion (8₂) between the two optical coupling parts 8₁ and 8₃ form the optical coupling part (7). In this case, the output end of the optical waveguide 52 for guiding green light is connected to the output optical waveguide 9 so as to output multiplexed light.

Alternatively, as illustrated in FIG. 4B, the optical waveguide 5₃ for guiding red light that disperses greatly, which is made in linear form, the optical waveguide 5₁ for guiding blue light which optically couples with the optical waveguide 5₃ for guiding red light, and the optical waveguide 5₂ for guiding green light which optically couples with the optical waveguide 5₃ for guiding red light form the optical multiplexing part (7). In this case, the output end of the optical waveguide 5₃ for guiding red light is connected to the output optical waveguide 9 so as to output multiplexed light. Here, the wavelength of light inputted into each optical waveguide 5₁ through 5₃ is arbitrary, and as illustrated in Example 5 below, green light may be inputted into the optical waveguide 5₁, and blue light may be inputted into the optical waveguide 5₃.

Alternatively, as shown in FIG. 4C, in the case where at least two light sources from among the plurality of light sources emit light of the same wavelength, the width of the optical waveguide 5₆ in linear form is made wider in the optical coupling part 8₆ for multiplexing the same wavelength so as to have an asymmetric structure. In the case where the optical coupling part 8₆ is formed of a directional coupler having a symmetric structure, light beams having the same color that have been inputted into the respective optical waveguides 5₃ and 5₄ are transferred to the opposite optical waveguides 5₄ and 5₃, and thus cannot be multiplexed with each other. Therefore, it is necessary to break the symmetry of the directional coupler so that only one light beam is transferred to the other side. In one example thereof, the width of the optical waveguide 5s is two times greater than the width of the optical waveguide 54. Any method other than the above from among various methods is possible as long as it provides an asymmetric structure.

The configuration for preventing the outer periphery of the light beam of which the light intensity distribution is in or below a range of at least 2.5 times greater than the full width at half maximum of that of the light beam that has failed to be inputted into the input optical waveguides 5₁ through 5₃ from overlapping with the multiplexed light is described again in reference to FIG. 1A. As illustrated in FIG. 1A, the axes along which the light beams are directed in proximity to the input ends of the plurality of input optical waveguides 5₁ through 5₃ may be provided at the locations that are away from the optical axis of the optical waveguide in linear form in the optical multiplexing unit 7. Alternatively, the output end 11 of the output optical waveguide 9 may be arranged at the location that is different from the optical axis of the optical waveguide in linear form in the optical multiplexing unit 7.

Alternatively, the output end 11 of the output optical waveguide 9 may be arranged in the direction of 85° to 95° relative to the optical axis of the optical waveguide in linear form in the optical multiplexing unit 7. In this case, a light beam that has failed to be inputted into the input optical waveguides 5₁ through 5₃ and stray light that has leaked out from the optical coupling units 8₁ through 8₃ in the optical multiplexing unit 7 so as to propagate through the clad portion 6 can surely be prevented from overlapping. Here, the output end 11 of the output optical waveguide 9 may be inclined by 90° relative to the optical axis of the optical waveguide in linear form in the optical multiplexing unit 7; however, the angle is set to 85° through 95° taking an error in the manufacture or the like into consideration.

Alternatively, the direction in which the light beams are guided in proximity to the input ends of the plurality of input optical waveguides 5₁ through 5₃ may be arranged so as to be directed at an angle of 85° through 95° relative to the optical axis of the optical waveguide in linear form in the optical multiplexing unit 7. In this case, the plurality of light sources 12₁ through 12₃ may be arranged along one side of the substrate 1 so that the direction in which the light beams are guided in proximity to the input ends of the plurality of input optical waveguides 5₁ through 5₃ is at an angle of 85° through 95° relative to the optical axis of the optical waveguide in linear form in the optical multiplexing unit 7. Alternatively, at least one from among the plurality of light sources 12₁ through 12₃ may be arranged along a first side of the substrate 1, and the remaining light sources may be arranged along a second side that faces the first side of the remaining input optical waveguides so that the direction in which the light beams are guided in proximity to the input ends of the plurality of input optical waveguides 5₁ through 5₃ is at an angle of 85° through 95° relative to the optical axis of the optical waveguide in linear form in the optical multiplexing unit 7.

As for the concrete configuration of the optical waveguides, as illustrated in FIG. 1B, the input optical waveguides 5₁ through 5₃, the respective optical waveguides in the optical multiplexing unit 7, and the output optical waveguide 9 may be formed of a common lower clad layer 2, cores in a core layer 3₁ through 3₃, and a common upper clad layer 4. Alternatively, the input optical waveguides 5₁ through 5₃ may be formed of individual lower clads in a lower clad layer, cores in a core layer 3₁ through 3₃, and individual upper clads in an upper clad layer, and the respective optical waveguides in the optical multiplexing unit 7 and the output optical waveguide 9 may be formed of individual lower clads in a lower clad layer, cores in a core layer 3₁ through 3₃, and a common upper clad layer 4. Alternatively, the input optical waveguides 5₁ through 5₃, the respective optical waveguides in the optical multiplexing unit 7, and the output optical waveguide 9 may be formed of a common lower clad layer 2, cores in a core layer 3₁ through 3₃, and individual upper clads in an upper clad layer.

Furthermore, a light shielding film for reflecting or absorbing clad mode light may be provided in a location where the multiplexed light from the output end 11 of the output optical waveguide 9 is not shielded in order to more surely prevent a light beam that has failed to be inputted into the input optical waveguides 5₁ through 5₃, that is to say, the clad mode light, from overlapping with the output light.

Here, any substrate such as an Si substrate, a glass substrate, a metal substrate or a plastic substrate may be used as the substrate 1. As for the material for the lower clad layer 2, the core layer 3₁ through 3₃ and the upper clad layer 4, an SiO₂ glass-based material can be used; however, a material other than these, for example, a transparent plastic such as an acrylic resin or other transparent materials, may be used.

In order to form a light source module, as illustrated in FIG. 1A, any of the above-described various types of optical multiplexers and a plurality of light sources 12₁ through 12₃ for inputting a light beam into the optical multiplexer may be combined. In this case, the light sources 12₁ through 12₃ are typically semiconductor lasers but may be light-emitting diodes. In addition, lenses may be provided between a plurality of light sources 12₁ through 12₃ and a plurality of input optical waveguides 5₁ through 5₃ in the optical multiplexer. Furthermore, optical fiber output ends may be installed in the locations of the light sources instead of the light sources 12₁ through 12₃ so that a light source device for guiding light outputted from the optical fibers to the optical multiplexer 7 can be provided.

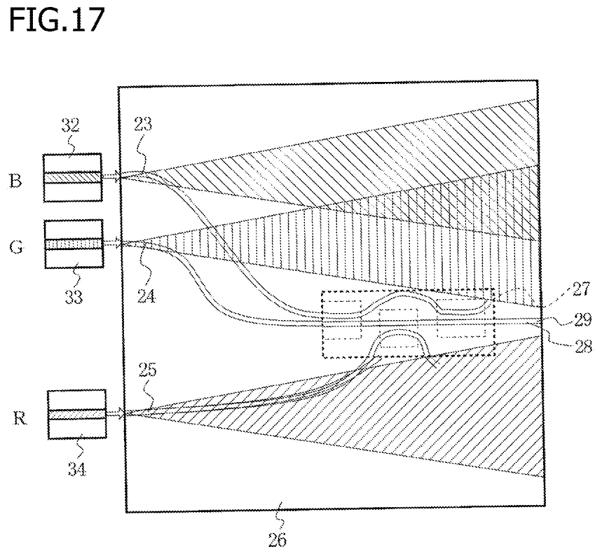

In order to form a two-dimensional optical scanning device, an optical multiplexing unit 27 in the two-dimensional optical scanning device as illustrated in FIG. 17 may be combined with any of the above-described various types of optical multiplexers. Furthermore, in order to form an image projection device, a two-dimensional scanning device as described above, a two-dimensional scanning control unit for two-dimensional scanning with emission light emitted from the light sources by applying a two-dimensional optical scanning signal to the electromagnetic coil 63 and an image formation unit for projecting an image scanned with the emission light onto a projection surface may be combined. Here, the image projection device is typically an eyeglass-type retina scanning display; however, in the case where an optical multiplexing unit as illustrated in FIG. 4C is used, the image projection device is an image formation device that requires intense light such as an HUD (head-up display).

### Example 1

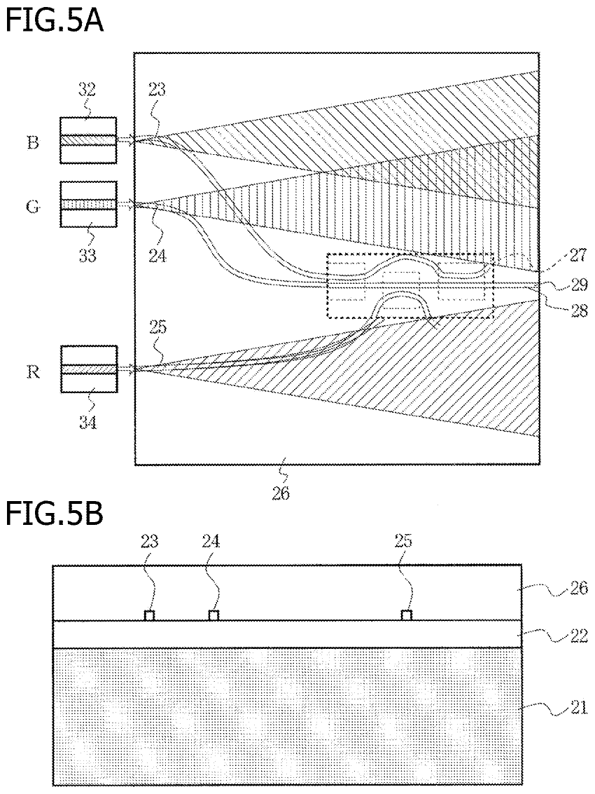

Here, the optical multiplexer in Example 1 of the present invention is described in reference to FIGS. 5A and 5B. FIGS. 5A and 5B are schematic diagrams illustrating the configuration of the optical multiplexer in Example 1 of the present invention. FIG. 5A is a schematic plan diagram, and FIG. 5B is a cross-sectional diagram on the input end side. Here, the optical multiplexer is illustrated as a light source module by adding light sources for the purpose of easy understanding of the invention. As illustrated in FIG. 5A, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in the optical multiplexing unit 27, and the multiplexed light that has been multiplexed in the optical multiplexing unit 27 is outputted from the output end 29 of an output optical waveguide 28. Here, the output end 29 of the output optical waveguide 28 may be a simple plane such as a plane of cleavage; however, the shape of the beam may be controlled by using a spot size converter or the like.

As illustrated in FIG. 5B, each optical waveguide from among the input optical waveguides 23 through 25, the respective optical waveguides in the optical multiplexing unit 27, and the output waveguide 9 is formed of a lower clad layer, which is an SiO₂ layer 22 having a thickness of 20 μm provided on top of an Si substrate 21 having a thickness of 1 mm and a (100) surface, a core layer having a width x a height of 2 μm×2 μm, which is formed by etching Ge-doped SiO₂ glass provided on top of the SiO₂ layer 22, and an upper clad layer 26 made of an SiO₂ layer having a thickness of 9 μm provided on top of the core layer (the thickness on top of the SiO₂ layer 22 becomes 11 μm). In this case, the difference in the refractive index between the core layer and the clad layer is 0.5%. Here, as for the size of the Si substrate 21, the length is 10 mm and the width is 3.7 mm.

The wavelength of light emitted from the blue semiconductor laser chip 32 is 450 nm, the total angle of the spread of the beam in the lateral direction (full width at half maximum) is 5 degrees, and the output is 10 mW. The wavelength of light emitted from the green semiconductor laser chip 33 is 520 nm, the total angle of the spread of the beam in the lateral direction is 7 degrees, and the output is 10 mW. The wavelength of light emitted from the red semiconductor laser chip 34 is 638 nm, the total angle of the spread of the beam in the lateral direction is 8 degrees, and the output is 10 mW. Here, the full width at half maximum (FWHM) is an angle at which the light intensity becomes half the intensity of the peak intensity.

The blue semiconductor laser chip 32, the green semiconductor laser chip 33 and the red semiconductor laser chip 34 are mounted in such a manner that the emission areas thereof are respectively matched with the entrance areas of the input optical waveguides 23 through 25 in the lateral direction and in the height direction with a gap vis-a-vis the input ends of the input optical waveguides 23 through 25 being 10 μm.

The structure of the optical multiplexing unit 27 is the same as that illustrated in FIG. 4A, and thus, an example thereof is described in reference to FIG. 4A, where the length of the optical coupling part 8₁ is 610 μm, the length of the optical coupling part 8₂ is 800 μm, and the length of the optical coupling part 8₃ is 610 μm. The optical waveguide 5₂ at the center of the optical waveguides is made linear, and thus, the number of portions at which an optical waveguide is bent is made smaller so that the entire size of the optical multiplexing unit can be made smaller. In this case, it is characteristic for the direction in which the laser is emitted to be approximately the same as the direction in which light progresses in the optical waveguide-type optical multiplexer. Here, the form of the input ends of the optical waveguides 23 through 25 may be altered to such a form as to be tapered in order to make it easier to take in light from each semiconductor laser.

Here, all the light beams emitted from the respective semiconductor lasers (32 through 34) are not guided into the core layer due to the difference in the shape between the light beams emitted from the semiconductor lasers (32 through 34) and the cores of the input optical waveguides 23 through 25 in the core layer, and partially leak into the clad portion made of the lower clad layer 22 and the upper clad layer so as to spread at a certain angle and propagate through the clad portion as illustrated in the figure. Concretely, light radiated from the blue semiconductor laser chip 32 propagates through the clad portion while spreading at an angle θ_{B}. Light radiated from the green semiconductor laser chip 33 propagates through the clad portion while spreading at an angle θ_{G}. In addition, light radiated from the red semiconductor laser chip 34 propagates through the clad portion while spreading at an angle θ_{R}.

The blue semiconductor laser chip 32, the green semiconductor laser chip 33, and the red semiconductor laser chip 34 are installed in such a manner that the output end 29 of the output optical waveguide 28 is not irradiated with all of the light radiated from the respective semiconductor laser chips, that is to say, the outer periphery of the entire radiated light does not overlap with the output end 29. Here, the blue semiconductor laser chip 32 and the green semiconductor laser chip 33 are arranged above the center line of the optical multiplexing unit 27, while the red semiconductor laser chip 34 is arranged beneath the center line.

As for the spread of the beam in the lateral direction in the clad portion after entering into the optical multiplexing unit 27, the total angle θ_{R} of the spread of the red laser beam in the lateral direction is 5.5 degrees, the total angle 6G of the spread of the green laser beam in the lateral direction is 4.8 degrees, and the total angle θ_{B} of the spread of the blue laser beam in the lateral direction is 3.5 degrees. Here, the total angle of the spread of the beam in the lateral direction, that is to say, the full width at half maximum, of the clad mode light is the outer periphery of the radiated light, and thus, this outer periphery of the radiated light is prevented from overlapping with the output end 29.

Incidentally, the relationship between the point at which the light beam from each semiconductor laser reaches an end portion of the substrate and the location of the output end 29 of the output optical waveguide 28 is as follows, taking the length of the Si substrate 21 being 10 mm into consideration. In the case of the red laser beam, it is necessary for the output end 29 to be away from the center of the red laser beam by d_{R}=10 mm×tan (θ_{R}/2) or more. In the case of the green laser beam, it is necessary for the output end 29 to be away from the center of the green laser beam by d_{G}=10 mm×tan (θ_{G}/2) or more. In the case of the blue laser beam, it is necessary for the output end 29 to be away from the center of the blue laser beam by d_{B}=10 mm×tan (θ_{B}/2) or more. In reality, the relationship with the arrangement of the lasers is also involved, and as for the relationship between the point at which the light beam from each semiconductor laser reaches an end portion of the substrate and the location of the output end 29 of the output optical waveguide 28, the output end 29 is at 0.8 mm away from the center of the red laser beam in the case of the red laser beam, the output end 29 is at 0.8 mm away from the center of the green laser beam in the case of the green laser beam, and the output end 29 is at 1.3 mm away from the center of the blue laser beam in the case of the blue laser beam. Here, there is a gap vis-a-vis the end surface (this is set at 10 μm), and therefore, the size of a light beam in the input end is not a point and has a finite size; however, the size is so small as to be negligible as compared to the size of the optical multiplexing unit 27, and thus is regarded as a point for calculating d_{R}, d_{G} and d_{B}.

In this manner, the outer periphery of each radiated beam can be prevented from overlapping with the output end 29 so that the ratio of the clad mode light that has mixed with the multiplexed signal light and propagated through the clad portion can be suppressed to 1% or less. Here, the outer periphery is at the full width at half maximum; however, in the case where it is necessary to further reduce noise light in order to gain an image with high definition, the outer periphery may be at 1.5 times greater than the full width at half maximum, and furthermore, in the case where an image with higher definition is necessary, the outer periphery may be 2.5 times greater than the full width at half maximum, and thus, the greater the outer periphery is as compared to the full width at half maximum, the smaller the effects of noise light become.

### Example 2

Next, the optical multiplexer in Example 2 of the present invention is described in reference to FIGS. 5A and 5B since the basic structure of the optical multiplexer in Example 2 is the same as the above-described optical multiplexer in Example 1. In the optical multiplexer in Example 2 of the present invention, light-emitting diodes (LEDs) are used as the light sources instead of semiconductor lasers. That is to say, a blue light-emitting LED chip is used in place of the blue semiconductor laser chip 32 in FIG. 5A, a green light-emitting LED chip is used in place of the green semiconductor laser chip 33, and a red light-emitting LED chip is used in place of the red semiconductor laser chip 34 accompanied with a slight change in the size of the respective components, and thus, the basic operation principles are the same with only a difference as to whether or not the light beams are lasers.

Here, an Si substrate having a thickness of 1 mm, a length of 10 mm, a width of 5.3 mm and a (100) surface is used as the Si substrate 21. The wavelength of light emitted from the red LED chip is 640 nm with the total angle of the spread of the beam in the lateral direction being 16 degrees and the output being 5 mW. The wavelength of light emitted from the green LED chip is 530 nm with the total angle of the spread of the beam in the lateral direction being 14 degrees and the output being 5 mW. The wavelength of light emitted from the blue LED chip is 450 nm with the total angle of the spread of the beam in the lateral direction being 10 degrees and the output being 5 mW.

As for the spread of the beam in the lateral direction in the clad portion after entering into the optical multiplexing unit 27, the total angle θ_{R} of the spread of the red beam in the lateral direction is 11 degrees, the total angle θ_{G} of the spread of the green beam in the lateral direction is 9.6 degrees, and the total angle θ_{B} of the spread of the blue beam in the lateral direction is 6.9 degrees. Here, the total angle of the spread of the beam in the lateral direction, that is to say, the full width at half maximum, of the clad mode light is the outer periphery of the radiated light, and this outer periphery of the radiated light is prevented from overlapping with the output end 29.

Incidentally, the relationship between the point at which the light beam from each LED reaches an end portion of the substrate and the location of the output end 29 of the output optical waveguide 28 is as follows, taking the length of the Si substrate 21 being 10 mm into consideration. In the case of the red beam, it is necessary for the output end 29 to be away from the center of the red beam by d_{R}=10 mm×tan (θ_{R}/2) or more. In the case of the green beam, it is necessary for the output end 29 to be away from the center of the green beam by d_{G}=10 mm×tan (θ_{G}/2) or more. In the case of the blue beam, it is necessary for the output end 29 to be away from the center of the blue beam by d_{B}=10 mm×tan (θ_{B}/2) or more. In reality, the relationship with the arrangement of LEDs is also involved, and thus, as for the relationship between the point at which the light beam from each LED reaches an end portion of the substrate and the location of the output end 29 of the output optical waveguide 28, the output end 29 is away from the center of the red beam by 1.6 mm in the case of the red beam, away from the center of the green beam by 1.6 mm in the case of the green beam, and away from the center of the blue beam by 2.1 mm in the case of the blue beam.

As described above, the outer periphery of each radiated beam is prevented from overlapping with the output end 29 in the case where light-emitting diodes are used as the light sources, and as a result, the ratio of the clad mode light that has mixed with the multiplexed signal light and propagated through the clad portion can be suppressed to 1% or less. Here, the outer periphery is the full width at half maximum; however, the outer periphery may be 1.5 times greater than the full width at half maximum of the clad mode light in the case where it is necessary to further reduce the noise light in order to gain an image with high definition, and furthermore, in the case where an image with higher definition is necessary, the outer periphery may be 2.5 times greater than the full width at half maximum, and thus, the greater the outer periphery is as compared to the full width at half maximum, the smaller the effects of noise light become.

### Example 3

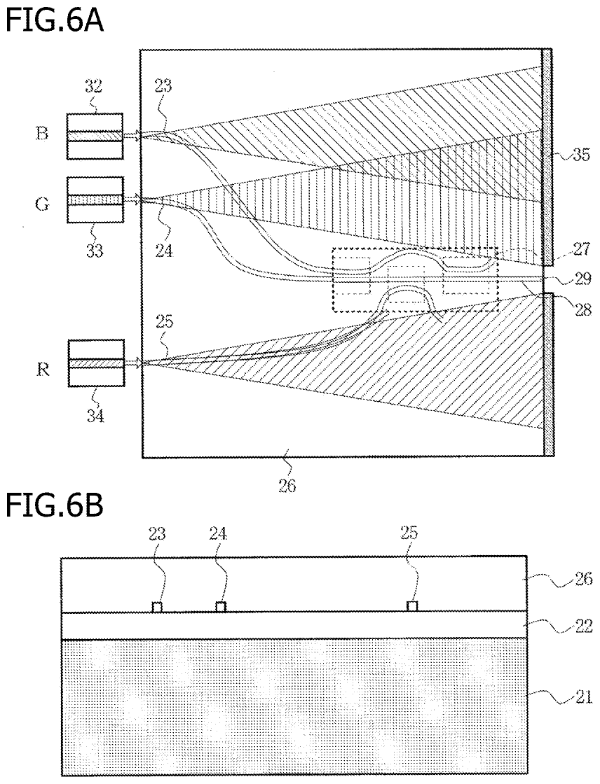

Next, the optical multiplexer in Example 3 of the present invention is described in reference to FIGS. 6A and 6B. The optical multiplexer in Example 3 is gained by providing a light shielding film on the output end side of the above-described optical multiplexer in Example 1, and the basic configuration and the operation principles are the same as in Example 1.

FIGS. 6A and 6B are schematic diagrams illustrating the configuration of the optical multiplexer in Example 3 of the present invention. FIG. 6A is a schematic plan diagram, and FIG. 6B is a cross-sectional diagram on the input end side. Here, the optical multiplexer is illustrated as a light source module by adding light sources for the purpose of easy understanding of the invention. As illustrated in FIG. 6A, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in the optical multiplexing unit 27, and the multiplexed light multiplexed in the optical multiplexing unit 27 is outputted from the output end 29 in the output optical waveguide 28. Here, the output end 29 of the output optical waveguide 28 may be a simple plane such as a plane of cleavage, and the shape of the beam may be controlled by using a spot size converter or the like.

As illustrated in FIG. 6B, each optical waveguide from among the input optical waveguides 23 through 25, the respective optical waveguides in the optical multiplexing unit 27, and the output waveguide 9 is formed of a lower clad layer, which is an SiO₂ layer 22 having a thickness of 20 μm provided on top of an Si substrate 21 having a thickness of 1 mm and a (100) surface, a core layer having a width x a height of 2 μm×2 μm, which is formed by etching Ge-doped SiO₂ glass provided on top of the SiO₂ layer 22, and an upper clad layer 26 made of an SiO₂ layer having a thickness of 9 μm provided on top of the core layer. In this case, the difference in the refractive index between the core layer and the clad layer is 0.5%. Here, as for the size of the Si substrate 21, the length is 10 mm and the width is 3.7 mm.

The wavelength of light emitted from the blue semiconductor laser chip 32 is 450 nm, the total angle of the spread of the beam in the lateral direction (full width at half maximum) is 5 degrees, and the output is 10 mW. The wavelength of light emitted from the green semiconductor laser chip 33 is 520 nm, the total angle of the spread of the beam in the lateral direction is 7 degrees, and the output is 10 mW. The wavelength of light emitted from the red semiconductor laser chip 34 is 638 nm, the total angle of the spread of the beam in the lateral direction is 8 degrees, and the output is 10 mW. Here, the full width at half maximum (FWHM) is an angle at which the light intensity becomes half the intensity of the peak intensity.

The blue semiconductor laser chip 32, the green semiconductor laser chip 33 and the red semiconductor laser chip 34 are mounted in such a manner that the emission areas thereof are respectively matched with the entrance areas of the input optical waveguides 23 through 25 in the lateral direction and in the height direction with a gap vis-a-vis the input ends of the input optical waveguides 23 through 25 being 10 μm. Here, a light shielding film 35 is provided so that a window of 4 μm×4 μm is created over the core of 2 μm×2 μm in the core layer on the output end 29 of the output optical waveguide 28 in the optical multiplexer. The light shielding film 35 is formed by applying a lift-off method to a vapor-deposited Al film having a thickness of 100 nm. In the case where the light shielding film 35 is formed as a reflection film, the material thereof is not limited to an Al film and a film of various types of metals can be used, or a light-absorbing film such as a resin film that includes carbon black may be used in place of the reflection film. Here, the structure of the optical multiplexing unit 27 is exactly the same as in Example 1.

In this case as well, the outer periphery of each radiated beam can be prevented from overlapping with the output end 29 so that the ratio of the clad mode light that has mixed with the multiplexed signal light and propagated through the clad portion can be suppressed to 1% or less. Here, the outer periphery is the full width at half maximum; however, the outer periphery may be 1.5 times greater than the full width at half maximum of the clad mode light in the case where it is necessary to further reduce the noise light in order to gain an image with high definition, and furthermore, in the case where an image with higher definition is necessary, the outer periphery may be 2.5 times greater than the full width at half maximum, and thus, the greater the outer periphery is as compared to the full width at half maximum, the smaller the effects of noise light become.

### Example 4

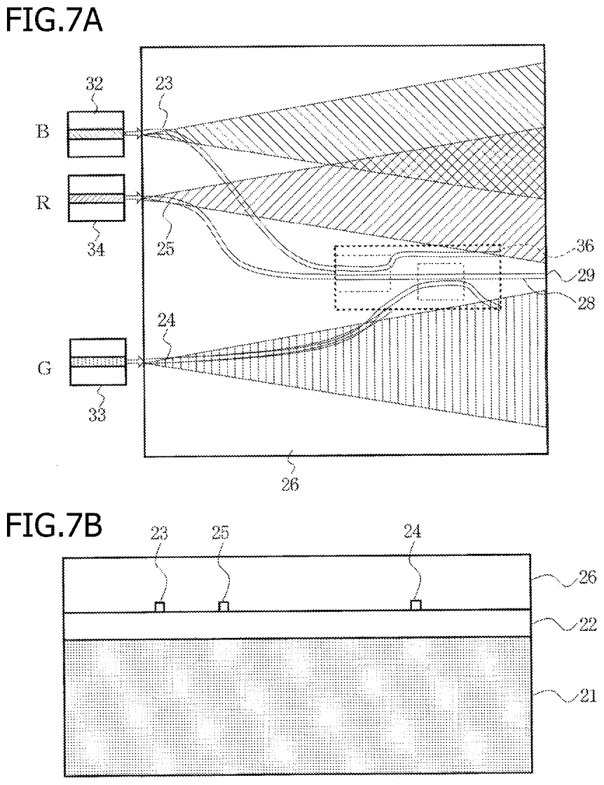

Next, the optical multiplexer in Example 4 of the present invention is described in reference to FIGS. 7A and 7B. The optical multiplexer in Example 4 is gained by replacing the above-described structure of the optical multiplexing unit in Example 1 with the structure illustrated in FIG. 4B. FIGS. 7A and 7B are schematic diagrams illustrating the configuration of the optical multiplexer in Example 4 of the present invention. FIG. 7A is a schematic plan diagram, and FIG. 7B is a cross-sectional diagram on the input end side. Here again, the optical multiplexer is illustrated as a light source module by adding light sources for the purpose of easy understanding of the invention. As illustrated in FIG. 7A, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in the optical multiplexing unit 36, and the multiplexed light that has been multiplexed in the optical multiplexing unit 36 is outputted from the output end 29 of an output optical waveguide 28. Here, the blue semiconductor laser chip 32 and the red semiconductor laser chip 34 are arranged above the center line of the optical multiplexing unit 36, while the green semiconductor laser chip 33 is arranged beneath the center line. In addition, the output end 29 of the output optical waveguide 28 may be a simple plane such as a plane of cleavage; however, the shape of the beam may be controlled by using a spot size converter or the like.

As illustrated in FIG. 7B, each optical waveguide from among the input optical waveguides 23 through 25, the respective optical waveguides in the optical multiplexing unit 27, and the output waveguide 28 is formed of a lower clad layer, which is an SiO₂ layer 22 having a thickness of 20 μm provided on top of an Si substrate 21 having a thickness of 1 mm and a (100) surface, a core layer having a width x a height of 2 μm×2 μm, which is formed by etching Ge-doped SiO₂ glass provided on top of the SiO₂ layer 22, and an upper clad layer 26 made of an SiO₂ layer having a thickness of 9 μm provided on top of the core layer. In this case, the difference in the refractive index between the core layer and the clad layer is 0.5%. Here, as for the size of the Si substrate 21, the length is 10 mm and the width is 3.7 mm.

The wavelength of light emitted from the blue semiconductor laser chip 32 is 450 nm, the total angle of the spread of the beam in the lateral direction (full width at half maximum) is 5 degrees, and the output is 10 mW. The wavelength of light emitted from the green semiconductor laser chip 33 is 520 nm, the total angle of the spread of the beam in the lateral direction is 7 degrees, and the output is 10 mW. The wavelength of light emitted from the red semiconductor laser chip 34 is 638 nm, the total angle of the spread of the beam in the lateral direction is 8 degrees, and the output is 10 mW.

The structure of the optical multiplexing unit 36 is the same as that illustrated in FIG. 4B, and thus, an example thereof is described in reference to FIG. 4B as follows. The length of the optical coupling part 8₄ is 1000 μm, and the length of the optical coupling part 8₅ is 1500 μm. The optical waveguide 5₃ at the center of the optical waveguides is selected as the one into which red light having the greatest dispersion enters so that the effects of the dispersion can be reduced. At the same time, the number of portions at which an optical waveguide is bent is made as small as two so that the entire size of the optical multiplexing unit can be made smaller. Here, the form of the input ends of the optical waveguides 23 through 25 may be altered to such a form as to be tapered in order to make it easier to take in light from each semiconductor laser. In addition, the gap d between the input end of each input optical waveguide 23 through 25 and the output end 29 of the output optical waveguide 28 in the arrangement satisfies d>10 mm×tan (θ/2).

In this case as well, in the same manner as in Example 2, LED chips may be used as the light sources instead of the semiconductor laser diode chips, or in the same manner as in Example 3, a light shielding film may be provided in proximity to the output end 29 of the output optical waveguide 28.

### Example 5

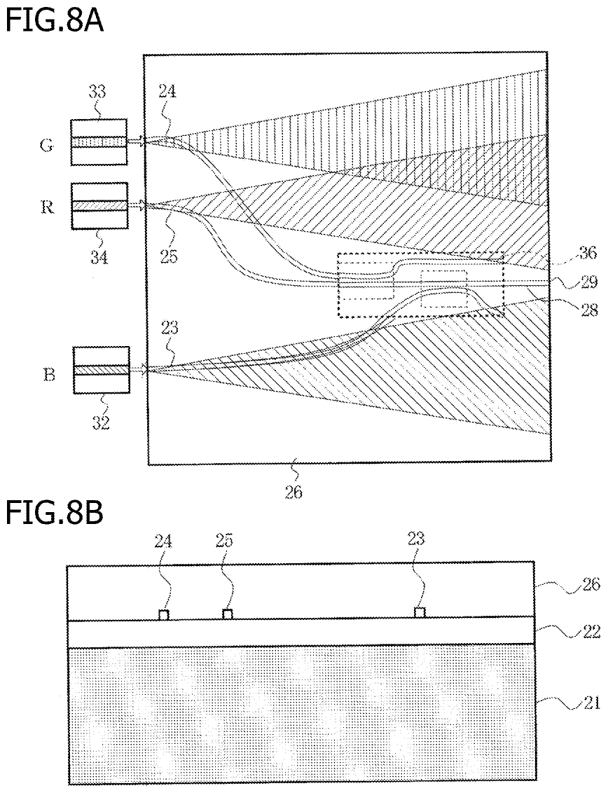

Next, the following description relates to the optical multiplexer in Example 5 of the present invention, which is the same as the above-described optical multiplexer in Example 4 except that the light beams inputted into the optical multiplexing unit are modified. FIGS. 8A and 8B are schematic diagrams illustrating the configuration of the optical multiplexer in Example 5 of the present invention. FIG. 8A is a schematic plan diagram, and FIG. 8B is a cross-sectional diagram on the input end side. Here again, the optical multiplexer is illustrated as a light source module by adding light sources for the purpose of easy understanding of the invention. As illustrated in FIG. 8A, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in an optical multiplexing unit 36 so that the multiplexed light multiplexed in the optical multiplexing unit 36 is outputted from the output end 29 of the output optical waveguide 28. Here, the green semiconductor laser chip 33 and the red semiconductor chip 34 are arranged above the center line of the optical multiplexing unit 36, and the blue semiconductor laser chip 32 is arranged beneath the center line. Here, the output end 29 of the output optical waveguide 28 may be a simple plane such as a plane of cleavage, and the shape of the beam may be controlled by using a spot size converter or the like.

As illustrated in FIG. 8B, each optical waveguide from among the input optical waveguides 23 through 25, the respective optical waveguides in the optical multiplexing unit 27, and the output waveguide 28 is formed of a lower clad layer, which is an SiO₂ layer 22 having a thickness of 20 μm provided on top of an Si substrate 21 having a thickness of 1 mm and a (100) surface, a core layer having a width x a height of 2 μm×2 μm, which is formed by etching Ge-doped SiO₂ glass provided on top of the SiO₂ layer 22, and an upper clad layer 26 made of an SiO₂ layer having a thickness of 9 μm provided on top of the core layer. In this case, the difference in the refractive index between the core layer and the clad layer is 0.5%. Here, as for the size of the Si substrate 21, the length is 10 mm and the width is 3.7 mm.

The wavelength of light emitted from the blue semiconductor laser chip 32 is 450 nm, the total angle of the spread of the beam in the lateral direction (full width at half maximum) is 5 degrees, and the output is 10 mW. The wavelength of light emitted from the green semiconductor laser chip 33 is 520 nm, the total angle of the spread of the beam in the lateral direction is 7 degrees, and the output is 10 mW. The wavelength of light emitted from the red semiconductor laser chip 34 is 638 nm, the total angle of the spread of the beam in the lateral direction is 8 degrees, and the output is 10 mW.

The structure of the optical multiplexing unit 36 is the same as that illustrated in FIG. 4B, and thus, an example thereof is described in reference to FIG. 4B as follows. The length of the optical coupling part 8₄ is 1000 μm, and the length of the optical coupling part 8₅ is 2000 μm. The optical waveguide 5₃ at the center of the optical waveguides is selected as the one into which red light having the greatest dispersion enters so that the effects of the dispersion can be reduced. At the same time, the number of portions at which an optical waveguide is bent is made as small as two so that the entire size of the optical multiplexing unit can be made smaller. Here, the form of the input ends of the optical waveguides 23 through 25 may be altered to such a form as to be tapered in order to make it easier to take in light from each semiconductor laser. In addition, the gap d between the input end of each input optical waveguide 23 through 25 and the output end 29 of the output optical waveguide 28 in the arrangement satisfies d>10 mm×tan (θ/2).

In this case as well, in the same manner as in Example 2, LED chips may be used as the light sources instead of the semiconductor laser diode chips, or in the same manner as in Example 3, a light shielding film may be provided in proximity to the output end 29 of the output optical waveguide 28.

### Example 6

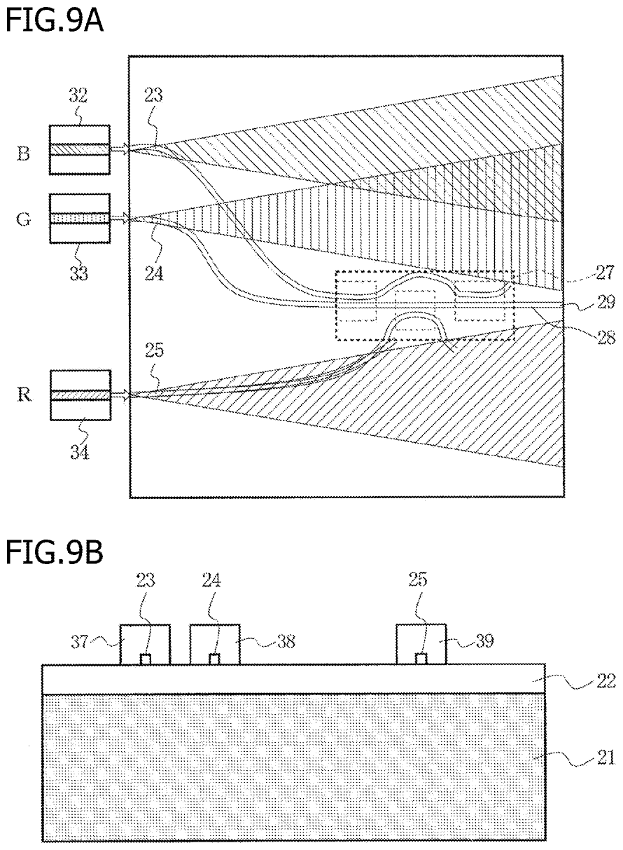

Next, the optical multiplexer in Example 6 of the present invention is described in reference to FIGS. 9A and 9B. The optical multiplexer in Example 6 is the same as the above-described optical multiplexer in Example 1 except the structure of the optical waveguides. FIGS. 9A and 9B are schematic diagrams illustrating the configuration of the optical multiplexer in Example 6 of the present invention. FIG. 9A is a schematic plan diagram, and FIG. 9B is a cross-sectional diagram on the input end side. Here again, the optical multiplexer is illustrated as a light source module by adding light sources for the purpose of easy understanding of the invention. As illustrated in FIG. 9A, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in an optical multiplexing unit 27 so that the multiplexed light multiplexed in the optical multiplexing unit 27 is outputted from the output end 29 of the output optical waveguide 28. Here, the output end 29 of the output optical waveguide 28 may be a simple plane such as a plane of cleavage, and the shape of the beam may be controlled by using a spot size converter or the like.

In each optical waveguide in Example 6 of the present invention, as illustrated in FIG. 9B, an SiO₂ layer 22 having a thickness of 20 μm is provided as a lower clad layer on top of an Si substrate 21 having a thickness of 1 mm and a (100) surface, cores having a width x a height of 2 μm×2 μm is formed by etching Ge-doped SiO₂ glass that is provided as a core layer on top of the SiO₂ layer 22, and an SiO₂ layer having a thickness of 9 μm is provided on top of the core layer as an upper clad layer from which upper clads 37 through 39 having a width of 10 μm are formed through etching. In this case, the optical waveguides in the optical multiplexing unit 27 and the output waveguide 28 have the same structure as the structure of the input optical waveguides 23 through 25. Here, the gap d between the input end of each input optical waveguide 23 through 25 and the output end 29 of the output optical waveguide 28 in the arrangement satisfies d>10 mm×tan (θ/2).

In this case as well, the outer periphery of each radiated beam is prevented from overlapping with the output end 29, and as a result, the ratio of the clad mode light that has mixed with the multiplexed signal light and propagated through the clad portion can be suppressed to 1% or less. Here again, the outer periphery may be defined as being 1.5 times greater than the full width at half maximum of the clad mode light or 2.5 times greater than the full width at half maximum, and thus, the greater the outer periphery is as compared to the full width at half maximum, the smaller the effects of noise light become. In addition, in the same manner as in Example 2, LED chips may be used as the light sources instead of the semiconductor laser diode chips; in the same manner as in Example 3, a light shielding film may be provided in proximity to the output end 29 of the output optical waveguide 28; or the optical multiplexing unit may have the same structure as in Example 4 or 5.

### Example 7

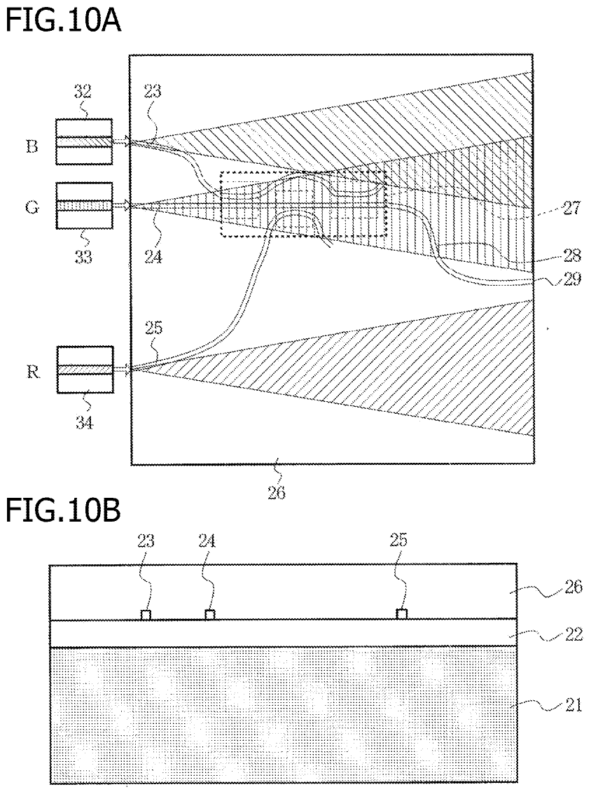

Next, the optical multiplexer in Example 7 of the present invention is described in reference to FIGS. 10A and 10B. The optical multiplexer in Example 7 is the same as the above-described optical multiplexer in Example 1 except the location in which the optical multiplexing unit is provided and the structure of the output optical waveguide. FIGS. 10A and 10B are schematic diagrams illustrating the configuration of the optical multiplexer in Example 7 of the present invention. FIG. 10A is a schematic plan diagram, and FIG. 10B is a cross-sectional diagram on the input end side. Here again, the optical multiplexer is illustrated as a light source module by adding light sources for the purpose of easy understanding of the invention. As illustrated in FIG. 10A, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in the optical multiplexing unit 27, and the multiplexed light that has been multiplexed in the optical multiplexing unit 27 is outputted from the output end 29 of an output optical waveguide 28. Here, the output end 29 of the output optical waveguide 28 may be a simple plane such as a plane of cleavage; however, the shape of the beam may be controlled by using a spot size converter or the like.

As illustrated in FIG. 10B, each optical waveguide from among the input optical waveguides 23 through 25, the respective optical waveguides in the optical multiplexing unit 27, and the output optical waveguide 28 is formed of a lower clad layer, which is an SiO₂ layer 22 having a thickness of 20 μm provided on top of an Si substrate 21 having a thickness of 1 mm and a (100) surface, a core layer having a width x a height of 2 μm×2 μm, which is formed by etching Ge-doped SiO₂ glass provided on top of the SiO₂ layer 22, and an upper clad layer 26 made of an SiO₂ layer having a thickness of 9 μm provided on top of the core layer. In this case, the difference in the refractive index between the core layer and the clad layer is 0.5%. Here, as for the size of the Si substrate 21, the length is 13 mm and the width is 4.1 mm.

In Example 7 of the present invention, the optical axis of the green semiconductor laser chip 33 is made to agree with the center axis of the optical multiplexing unit 27, and at the same time, the output optical waveguide 28 is bent so that the gap between the input optical waveguide 24 and the output optical waveguide 28 in proximity to the output end 29 is set to 1.0 mm, and thus, the location of the output end 29 is prevented from overlapping with the outer peripheries of the respective beams of clad mode light.

In this case as well, the outer periphery of each radiated beam can be prevented from overlapping with the output end 29 so that the ratio of the clad mode light that has mixed with the multiplexed signal light and propagated through the clad portion can be suppressed to 1% or less. In this case, the light that has leaked out from an optical coupling unit in the optical multiplexing unit 27 does not overlap with the multiplexed light emitted from the output end 29, and therefore, the effects of noise light can further be reduced. Here again, the outer periphery may be defined as being 1.5 times greater than the full width at half maximum of the clad mode light or 2.5 times greater than the full width at half maximum, and thus, the greater the outer periphery is as compared to the full width at half maximum, the smaller the effects of noise light become. In addition, in the same manner as in Example 2, LED chips may be used as the light sources instead of the semiconductor laser diode chips; in the same manner as in Example 3, a light shielding film may be provided in proximity to the output end 29 of the output optical waveguide 28; or the optical multiplexing unit may have the same structure as in Example 4 or 5.

### Example 8

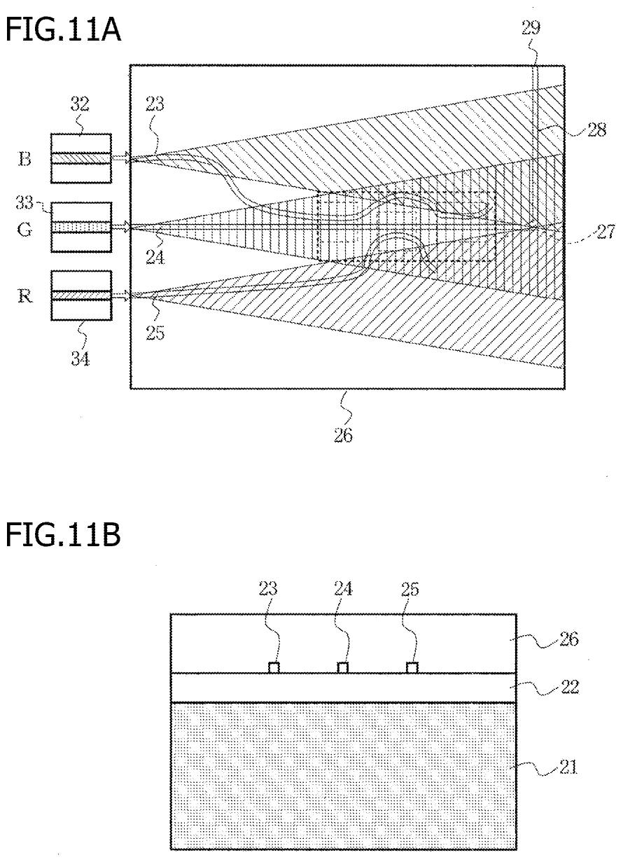

Next, the optical multiplexer in Example 8 of the present invention is described in reference to FIGS. 11A and 11B. The optical multiplexer in Example 8 is the same as the above-described optical multiplexer in Example 1 except the location in which the optical multiplexing unit is provided, the arrangement of the light sources and the structure of the output optical waveguide. FIGS. 11A and 11B are schematic diagrams illustrating the configuration of the optical multiplexer in Example 8 of the present invention. FIG. 11A is a schematic plan diagram, and FIG. 11B is a cross-sectional diagram on the input end side. Here again, the optical multiplexer is illustrated as a light source module by adding light sources for the purpose of easy understanding of the invention.

As illustrated in FIG. 11A, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in the optical multiplexing unit 27, and the multiplexed light that has been multiplexed in the optical multiplexing unit 27 is outputted from the output end 29 of the output optical waveguide 28. Here, the blue semiconductor laser chip 32, the green semiconductor laser chip 33 and the red semiconductor laser chip 34 are arranged at approximately the same intervals. The optical axis of the green semiconductor laser chip 33 and the center axis of the optical multiplexing unit 27 are made to agree with each other, and at the same time, the optical axis of the output optical waveguide 28 is inclined by 85° to 95° relative to the center axis of the optical multiplexing unit 27 by means of a waveguide-type reflection mirror at 0.5 mm to the rear of the output end of the optical multiplexing unit 27. Here, the inclination is 90°. In this case, the waveguide is bent at a right angle by using a waveguide-type reflection mirror; however, a bent waveguide having a curvature may of course be used.

In Example 8, as for the size of the Si substrate 21, the length is 13.5 mm and the width is 4 mm. In this case, the outer periphery of the clad mode light from the blue semiconductor laser chip 32 is prevented from overlapping with the output end 29 of the output optical waveguide 28. Here, the gap between the input end of the input optical waveguide 23 and the output end 29 of the output optical waveguide 28 is 1.0 mm in the arrangement, the gap between the input end of the input optical waveguide 24 and the output end 29 of the output optical waveguide 28 is 2.0 mm in the arrangement, and the gap between the input end of the input optical waveguide 25 and the output end 29 of the output optical waveguide 28 is 3.0 mm in the arrangement.

In this case as well, the outer periphery of each radiated beam can be prevented from overlapping with the output end 29 so that the ratio of the clad mode light that has mixed with the multiplexed signal light and propagated through the clad portion can be suppressed to 1% or less. In this case, the light that has leaked out from an optical coupling unit in the optical multiplexing unit 27 does not overlap with the multiplexed light emitted from the output end 29, and therefore, the effects of noise light can further be reduced. Here again, the outer periphery may be defined as being 1.5 times greater than the full width at half maximum of the clad mode light or 2.5 times greater than the full width at half maximum, and thus, the greater the outer periphery is as compared to the full width at half maximum, the smaller the effects of noise light become. In addition, in the same manner as in Example 2, LED chips may be used as the light sources instead of the semiconductor laser diode chips; in the same manner as in Example 3, a light shielding film may be provided in proximity to the output end 29 of the output optical waveguide 28 by way of precaution; or the optical multiplexing unit may have the same structure as in Example 4 or 5.

### Example 9

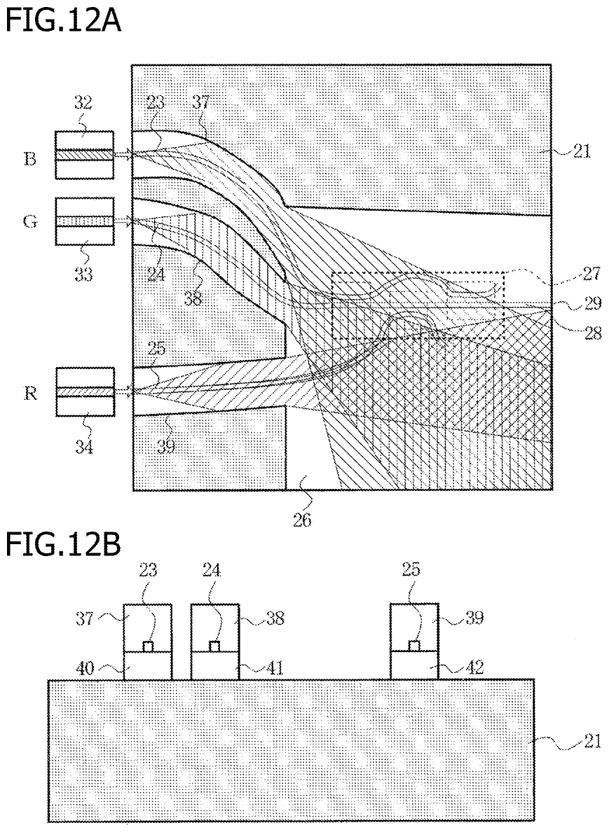

Next, the optical multiplexer in Example 9 of the present invention is described in reference to FIGS. 12A and 12B. The optical multiplexer in Example 9 is the same as the above-described optical multiplexer in Example 1 except the structure of the optical waveguides. FIGS. 12A and 12B are schematic diagrams illustrating the configuration of the optical multiplexer in Example 9 of the present invention. FIG. 12A is a schematic plan diagram, and FIG. 12B is a cross-sectional diagram on the input end side. Here again, the optical multiplexer is illustrated as a light source module by adding light sources for the purpose of easy understanding of the invention.

As illustrated in FIG. 12A, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in the optical multiplexing unit 27, and the multiplexed light that has been multiplexed in the optical multiplexing unit 27 is outputted from the output end 29 of the output optical waveguide 28. Here, the output end 29 of the output optical waveguide 28 may be a simple plane such as a plane of cleavage; however, the shape of the beam may be controlled by using a spot size converter or the like.

In Example 9 of the present invention, as illustrated in FIG. 12B, each optical waveguide from among the input optical waveguides 23 through 25 is formed of a lower clad layer, which is an SiO₂ layer 22 provided on top of an Si substrate 21 having a thickness of 1 mm and a (100) surface, a core layer having a width x a height of 2 μm×2 μm, which is formed by etching Ge-doped SiO₂ glass provided on top of the SiO₂ layer 22, and an SiO₂ layer having a thickness of 9 μm provided on top of the core layer, where the SiO₂ layer on top of the core layer is etched after having been provided so as to form clad portions having a width of 20 μm and a height of 20 μm that surround the cores and are made of an upper core layer 37 through 39 and a lower clad layer 40 through 42. The structures of the optical multiplexing unit 27 and the output optical waveguide 28 are the same as in Example 1. As for the form of the upper clad layer 26, the length is 5.5 mm and the width is 1.8 mm. Unlike the clad in Example 1, the clad in this example is not formed in a layer form that covers the Si substrate 21, and the place where it lies is limited to only the area in proximity to the core layer. As a result, the area of the clad layer is made smaller, which makes it possible to reduce the material costs or the process costs.

In the case where each clad portion surrounds a core and lies only in proximity to the lower clad layer, light that has failed to enter into the input optical waveguides 23 through 25 propagates through the lower clad layer so as to be guided to the optical multiplexing unit 27 together with light in the core layer. This takes place because the amount of light that propagates through this clad layer cannot be neglected in the case where the size of the optical multiplexer is small, even when the substrate beneath the lower clad layer has a refractive index that is greater than that of the lower clad layer or is a light absorbing layer.

Accordingly, light leaks out to the clad portion having layers in the connection portion between an upper clad layer 37 through 39 and the upper clad layer 26 so as to disseminate, and the shape of the lower clad in the lower clad layer is determined so that the output end 29 of the output optical waveguide 28 is not irradiated with the outer periphery of the radiated light that has disseminated. That is to say, light that was emitted from each semiconductor laser and has propagated through an individual clad portion spreads in the lateral direction at a certain angle θ in the connection portion between an upper clad layer 37 through 39 and the upper clad layer 26 after the upper clad layer 37 through 39 and the upper clad layer 26 are connected so as to provide layers in the clad portion. Accordingly, in this case as well, the optical coupling unit 27 is arranged so that the outer periphery of each light beam radiated from the connection portion between the upper clad layer 37 through 39 and the upper clad layer 26 does not overlap with the multiplexed light emitted from the output end 29 of the output optical waveguide 28. Here, the length of the perpendicular from the output end 29 to the center axis of the blue laser beam that spreads from the connection portion between the upper clad layer 37 through 39 and the upper clad layer 26 is 1.75 mm. The length of the perpendicular from the output end 29 to the center axis of the green laser beam that spreads from the connection portion between the upper clad layer 37 through 39 and the upper clad layer 26 is 1.75 mm. The length of the perpendicular from the output end 29 to the center axis of the red laser beam that spreads from the connection portion between the upper clad layer 37 through 39 and the upper clad layer 26 is 0.8 mm.

In this case as well, the outer periphery of each radiated beam is prevented from overlapping with the output end 29, and as a result, the ratio of the clad mode light that has mixed with the multiplexed signal light and propagated through the clad portion can be suppressed to 1% or less. Here again, the outer periphery may be defined as being 1.5 times greater than the full width at half maximum of the clad mode light or 2.5 times greater than the full width at half maximum, and thus, the greater the outer periphery is as compared to the full width at half maximum, the smaller the effects of noise light become. In addition, in the same manner as in Example 2, LED chips may be used as the light sources instead of the semiconductor laser diode chips; in the same manner as in Example 3, a light shielding film may be provided in proximity to the output end 29 of the output optical waveguide 28; or the optical multiplexing unit may have the same structure as in Example 4 or 5.

### Example 10

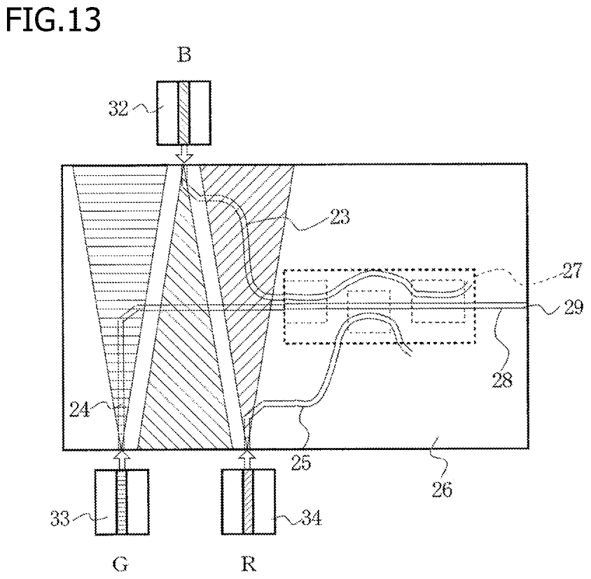

Next, the optical multiplexer in Example 10 of the present invention is described in reference to FIG. 13. The optical multiplexer in Example 10 is the same as the above-described optical multiplexer in Example 1 except the arrangement of the light sources and the structures of the input optical waveguides that connect the light sources to the optical multiplexing unit. FIG. 13 is a schematic plan diagram illustrating the configuration of the optical multiplexer in Example 10 of the present invention. Here again, the optical multiplexer is illustrated as a light source module by adding light sources for the purpose of easy understanding of the invention.

As illustrated in FIG. 13, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in the optical multiplexing unit 27, and the multiplexed light that has been multiplexed in the optical multiplexing unit 27 is outputted from the output end 29 of the output optical waveguide 28. Here, the output end 29 of the output optical waveguide 28 may be a simple plane such as a plane of cleavage; however, the shape of the beam may be controlled by using a spot size converter or the like.

In Example 10 of the present invention, as illustrated in FIGS. 12A and 12B, the blue semiconductor laser chip 32 is arranged along one long side of the Si substrate, and the green semiconductor laser chip 33 and the red semiconductor laser chip 34 are arranged along the other long side of the Si substrate. Here, the optical axis of each semiconductor laser and the center axis of the optical multiplexing unit 27 cross at an angle of 90°; however, the crossing angle is arbitrary and may be in a range from 85° to 95°, taking an error in the manufacture into consideration. Here, the length of the Si substrate is 7 mm and the width is 2.6 mm. Therefore, the structure makes the input optical waveguides 23 through 25 bent in the middle at a right angle. In order to bend the optical waveguides at a right angle, a waveguide-type reflection mirror is used; however, a bent waveguide having a small curvature radius may be used.

In this case, it is desirable for the active layer portion of a first semiconductor laser chip to be prevented from being irradiated with the light beam emitted from a second semiconductor laser chip, where the first and second semiconductor laser chips are any two from among the blue semiconductor laser chip 32, the green semiconductor laser chip 33 and the red semiconductor laser chip 34 that face each other. The configuration where the active layer portion of a first semiconductor laser chip that faces a second semiconductor laser chip is prevented from being irradiated with the light beam emitted from the second semiconductor laser chip is more desirable because such a configuration makes the oscillation of each semiconductor laser chip stable, and thus makes the semiconductor laser chips function as multiplexing light sources providing a high-speed, stable signal operation. Here, even in the case where the active layer portion of a first semiconductor laser chip is irradiated with the light beam emitted from a second semiconductor laser chip, the oscillations of the semiconductor lasers are still stable, and thus, the semiconductors function as multiplexing light sources providing a high-speed, stable signal operation at least when the wavelength of the second semiconductor laser is longer than the wavelength of the first semiconductor laser. Here, the gap between the input end of the input optical waveguide 23 and the output end 29 of the output optical waveguide 28 is 6.0 mm in the arrangement, the gap between the input end of the input optical waveguide 24 and the output end 29 of the output optical waveguide 28 is 6.5 mm in the arrangement, and the gap between the input end of the input optical waveguide 25 and the output end 29 of the output optical waveguide 28 is 5.5 mm in the arrangement.

In this case as well, the outer periphery of each radiated beam is prevented from overlapping with the output end 29, and as a result, the ratio of the clad mode light that has mixed with the multiplexed signal light and propagated through the clad portion can be suppressed to 1% or less. In this case, the light that has leaked out from an optical coupling unit in the optical multiplexing unit 27 does not overlap with the multiplexed light emitted from the output end 29, and therefore, the effects of noise light can further be reduced. In addition, the modulation of each semiconductor laser was increased as high as 100 MHz without causing a signal distortion. Here again, the outer periphery may be defined as being 1.5 times greater than the full width at half maximum of the clad mode light or 2.5 times greater than the full width at half maximum, and thus, the greater the outer periphery is as compared to the full width at half maximum, the smaller the effects of noise light become. Furthermore, in the same manner as in Example 2, LED chips may be used as the light sources instead of the semiconductor laser diode chips; in the same manner as in Example 3, a light shielding film may be provided in proximity to the output end 29 of the output optical waveguide 28; or the optical multiplexing unit may have the same structure as in Example 4 or 5.

### Example 11

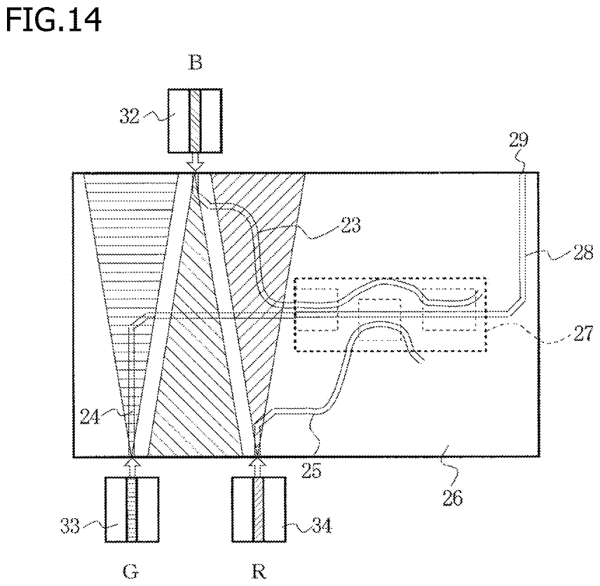

Next, the optical multiplexer in Example 11 of the present invention is described in reference to FIG. 14. The optical multiplexer in Example 11 is the same as the above-described optical multiplexer in Example 10 except the structure of the output optical waveguide. FIG. 14 is a schematic plan diagram illustrating the configuration of the optical multiplexer in Example 11 of the present invention. Here again, the optical multiplexer is illustrated as a light source module by adding light sources for the purpose of easy understanding of the invention.

As illustrated in FIG. 14, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in the optical multiplexing unit 27, and the multiplexed light that has been multiplexed in the optical multiplexing unit 27 is outputted from the output end 29 of the output optical waveguide 28. Here, the output end 29 of the output optical waveguide 28 may be a simple plane such as a plane of cleavage; however, the shape of the beam may be controlled by using a spot size converter or the like.

In Example 11 of the present invention as well, as illustrated in FIG. 14, the blue semiconductor laser chip 32 is arranged along one long side of the Si substrate, and the green semiconductor laser chip 33 and the red semiconductor laser chip 34 are arranged along the other long side of the Si substrate. Here, the optical axis of each semiconductor laser and the center axis of the optical multiplexing unit 27 cross at an angle of 90°; however, the crossing angle is arbitrary and may be in a range from 85° to 95°, taking an error in the manufacture into consideration. Here, the length of the Si substrate is 7 mm and the width is 2.6 mm.

In Example 11 of the present invention, the optical axis of the output optical waveguide 28 is inclined by 85° to 95° relative to the center axis of the optical multiplexing unit 27 by means of a waveguide-type reflection mirror at 0.5 mm to the rear of the output end of the optical multiplexing unit 27. Here, the inclination is 90°. In this case, the waveguide is bent at a right angle by using a waveguide-type reflection mirror; however, a bent waveguide having a curvature may of course be used. Here, the gap between the input end of the input optical waveguide 23 and the output end 29 of the output optical waveguide 28 is 6.0 mm in the arrangement, the gap between the input end of the input optical waveguide 24 and the output end 29 of the output optical waveguide 28 is 6.5 mm in the arrangement, and the gap between the input end of the input optical waveguide 25 and the output end 29 of the output optical waveguide 28 is 5.5 mm in the arrangement.

In the same manner as in Example 10, it is desirable for the active layer portion of a first semiconductor laser chip to be prevented from being irradiated with the light beam emitted from a second semiconductor laser chip, where the first and second semiconductor laser chips are any two from among the blue semiconductor laser chip 32, the green semiconductor laser chip 33 and the red semiconductor laser chip 34 that face each other. The configuration where the active layer portion of a first semiconductor laser chip that faces a second semiconductor laser chip is prevented from being irradiated with the light beam emitted from the second semiconductor laser chip is more desirable because such a configuration makes the oscillation of each semiconductor laser chip stable, and thus makes the semiconductor laser chips function as multiplexing light sources providing a high-speed, stable signal operation. Here, even in the case where the active layer portion of a first semiconductor laser chip is irradiated with the light beam emitted from a second semiconductor laser chip, the oscillations of the semiconductor lasers are still stable, and thus, the semiconductors function as multiplexing light sources providing a high-speed, stable signal operation at least when the wavelength of the second semiconductor laser is longer than the wavelength of the first semiconductor laser.

In this case as well, the outer periphery of each radiated beam is prevented from overlapping with the output end 29, and as a result, the ratio of the clad mode light that has mixed with the multiplexed signal light and propagated through the clad portion can be suppressed to 1% or less. In this case, the light that has leaked out from an optical coupling unit in the optical multiplexing unit 27 does not overlap with the multiplexed light emitted from the output end 29, and therefore, the effects of noise light can further be reduced. In addition, the modulation of each semiconductor laser was increased as high as 100 MHz without causing a signal distortion. Here again, the outer periphery may be defined as being 1.5 times greater than the full width at half maximum of the clad mode light or 2.5 times greater than the full width at half maximum, and thus, the greater the outer periphery is as compared to the full width at half maximum, the smaller the effects of noise light become. Furthermore, in the same manner as in Example 2, LED chips may be used as the light sources instead of the semiconductor laser diode chips; in the same manner as in Example 3, a light shielding film may be provided in proximity to the output end 29 of the output optical waveguide 28; or the optical multiplexing unit may have the same structure as in Example 4 or 5.

### Example 12

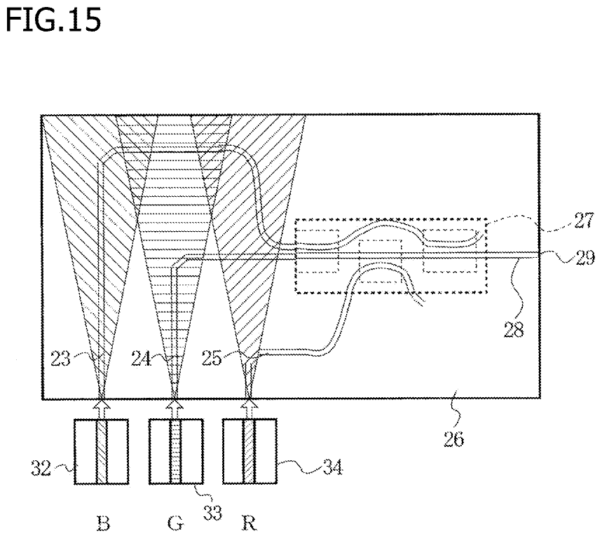

Next, the optical multiplexer in Example 12 of the present invention is described in reference to FIG. 15. The optical multiplexer in Example 12 is the same as the above-described optical multiplexer in Example 1 except the arrangement of the light sources and the structures of the input optical waveguides that connect the light sources to the optical multiplexing unit. FIG. 15 is a schematic plan diagram illustrating the configuration of the optical multiplexer in Example 12 of the present invention. Here again, the optical multiplexer is illustrated as a light source module by adding light sources for the purpose of easy understanding of the invention.

As illustrated in FIG. 15, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in the optical multiplexing unit 27, and the multiplexed light that has been multiplexed in the optical multiplexing unit 27 is outputted from the output end 29 of the output optical waveguide 28. Here, the output end 29 of the output optical waveguide 28 may be a simple plane such as a plane of cleavage; however, the shape of the beam may be controlled by using a spot size converter or the like.

In Example 12 of the present invention, as illustrated in FIG. 15, the blue semiconductor laser chip 32, the green semiconductor laser chip 33 and the red semiconductor laser chip 34 are arranged along one long side of the Si substrate. Here, the optical axis of each semiconductor laser and the center axis of the optical multiplexing unit 27 cross at an angle of 90°; however, the crossing angle is arbitrary and may be in a range from 85° to 95°, taking an error in the manufacture into consideration. Here, the length of the Si substrate is 17 mm and the width is 2.6 mm. Thus, the structure makes the input optical waveguides 23 through 25 bent in the middle at a right angle. In order to bend the optical waveguides at a right angle, a waveguide-type reflection mirror is used; however, a bent waveguide having a small curvature radius may be used. Here, the gap between the input end of the input optical waveguide 23 and the output end 29 of the output optical waveguide 28 is 6.5 mm in the arrangement, the gap between the input end of the input optical waveguide 24 and the output end 29 of the output optical waveguide 28 is 6.0 mm in the arrangement, and the gap between the input end of the input optical waveguide 25 and the output end 29 of the output optical waveguide 28 is 5.5 mm in the arrangement.

In this case, the blue semiconductor laser chip 32, the green semiconductor laser chip 33 and the red semiconductor laser chip 34 are arranged along the same side of the substrate, and therefore, the active layer portion of a first semiconductor laser chip is not irradiated with the light beam emitted from a second semiconductor laser chip, where the first and second semiconductor laser chips are any two of the blue semiconductor laser chip 32, the green semiconductor laser chip 33 and the red semiconductor laser chip 34 that face each other. Accordingly, a more desirable configuration is gained where the oscillations of the respective semiconductor laser chips are stable, and the semiconductor laser chips function as multiplexed light sources providing a high-speed, stable signal operation.

In this case as well, the outer periphery of each radiated beam is prevented from overlapping with the output end 29, and as a result, the ratio of the clad mode light that has mixed with the multiplexed signal light and propagated through the clad portion can be suppressed to 1% or less. In this case, the light that has leaked out from an optical coupling unit in the optical multiplexing unit 27 does not overlap with the multiplexed light emitted from the output end 29, and therefore, the effects of noise light can further be reduced. In addition, the modulation of each semiconductor laser was increased as high as 100 MHz without causing a signal distortion. Here again, the outer periphery may be defined as being 1.5 times greater than the full width at half maximum of the clad mode light or 2.5 times greater than the full width at half maximum, and thus, the greater the outer periphery is as compared to the full width at half maximum, the smaller the effects of noise light become. Furthermore, in the same manner as in Example 2, LED chips may be used as the light sources instead of the semiconductor laser diode chips.

### Example 13

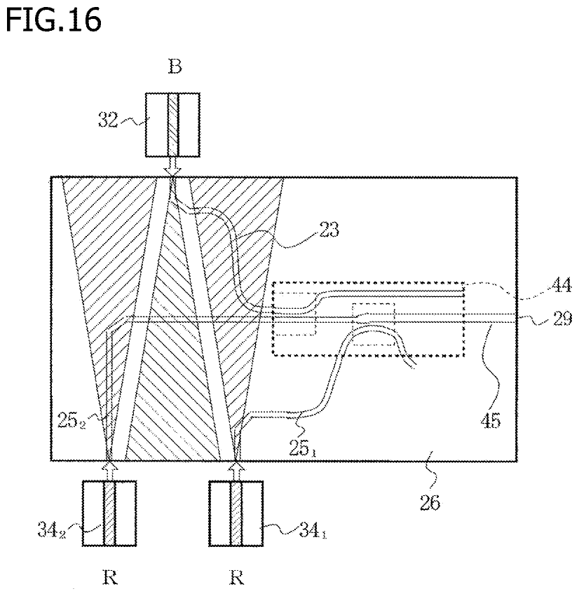

Next, the optical multiplexer in Example 13 of the present invention is described in reference to FIG. 16. The optical multiplexer in Example 13 is the same as the above-described optical multiplexer in Example 10 except the structure of the optical multiplexing unit and the wavelength of light emitted from at least two light sources being the same. FIG. 16 is a schematic plan diagram illustrating the configuration of the optical multiplexer in Example 13 of the present invention. Here again, the optical multiplexer is illustrated as a light source module by adding light sources for the purpose of easy understanding of the invention.

As illustrated in FIG. 16, the light beam from a blue semiconductor laser chip 32 is inputted into an input optical waveguide 23, and the light beams from two red semiconductor laser chips 34₁ and 34₂ are inputted into two input optical waveguides 25₁ and 25₂. The input optical waveguides 23, 25₁ and 25₂ are connected to the optical waveguides in the optical multiplexing unit 44, and the multiplexed light that has been multiplexed in the optical multiplexing unit 44 is outputted from the output end 29 of the output optical waveguide 45. Here, the output end 29 of the output optical waveguide 28 may be a simple plane such as a plane of cleavage; however, the shape of the beam may be controlled by using a spot size converter or the like. Here, the gap between the input end of the input optical waveguide 23 and the output end 29 of the output optical waveguide 28 is 6.0 mm in the arrangement, the gap between the input end of the input optical waveguide 25₂ and the output end 29 of the output optical waveguide 28 is 6.5 mm in the arrangement, and the gap between the input end of the input optical waveguide 25₁ and the output end 29 of the output optical waveguide 28 is 5.5 mm in the arrangement.

The structure of the optical multiplexing unit in Example 13 of the present invention is the same that is illustrated in FIG. 4C, and therefore, the description is made in reference to FIG. 4C. As illustrated in FIG. 4C, the optical waveguide 5₆ in linear form in the optical coupling part 8₆ for multiplexing red laser light is widened in the width so as to provide an asymmetric structure. In the case where the optical coupling part 8₆ is formed of a directional coupler having a symmetric structure, light of the same color that has entered into the optical waveguides 5₃ and 5₄ respectively transfers to the optical waveguides 5₄ and 5₃ that are opposite to each other, and thus cannot be multiplexed. As a result, it is necessary to break the symmetry of the directional coupler so that light transfers to only one optical waveguide. In an example thereof, the width of the optical waveguide 5₆ is made two times greater than the width of the optical waveguide 5₄. Any structure can be used as long as it is asymmetric, and various methods for providing such a structure are possible.

In Example 13 of the present invention, light beams having the same wavelength can be multiplexed so as to increase the output, and therefore, the optical multiplexer can be applied to an image formation device that requires intense light such as an HUD (head-up display).

In this case as well, the outer periphery of each radiated beam is prevented from overlapping with the output end 29, and as a result, the ratio of the clad mode light that has mixed with the multiplexed signal light and propagated through the clad portion can be suppressed to 1% or less. In this case, the light that has leaked out from an optical coupling unit in the optical multiplexing unit 27 does not overlap with the multiplexed light emitted from the output end 29, and therefore, the effects of noise light can further be reduced. Here again, the outer periphery may be defined as being 1.5 times greater than the full width at half maximum of the clad mode light or 2.5 times greater than the full width at half maximum, and thus, the greater the outer periphery is as compared to the full width at half maximum, the smaller the effects of noise light become. Furthermore, in the same manner as in Example 2, LED chips may be used as the light sources instead of the semiconductor laser diode chips; in the same manner as in Example 3, a light shielding film may be provided in proximity to the output end 29 of the output optical waveguide 28.

### Example 14

Next, the light source module in Example 14 of the present invention is described in reference to FIG. 17. The light source module in Example 14 is exactly the same as the light source module illustrated in FIGS. 5A and 5B where light sources are added to the optical multiplexer for the purpose of description. FIG. 17 is a schematic diagram illustrating the configuration of the optical multiplexer in Example 14 of the present invention. As illustrated in FIG. 17, the light beam from a blue semiconductor laser chip 32 is inputted into an input optical waveguide 23, the light beam from a green semiconductor laser chip 33 is inputted into an input optical waveguide 24, and the light beam from a red semiconductor laser chip 34 is inputted into an input optical waveguide 25. The input optical waveguides 23 through 25 are connected to the optical waveguides in the optical multiplexing unit 27, and the multiplexed light that has been multiplexed in the optical multiplexing unit 27 is outputted from the output end 29 of the output optical waveguide 28. Here, the output end 29 of the output optical waveguide 28 may be a simple plane such as a plane of cleavage; however, the shape of the beam may be controlled by using a spot size converter or the like.

The wavelength of light emitted from the blue semiconductor laser chip 32 is 450 nm, the total angle of the spread of the beam in the lateral direction (full width at half maximum) is 5 degrees, and the output is 10 mW. The wavelength of light emitted from the green semiconductor laser chip 33 is 520 nm, the total angle of the spread of the beam in the lateral direction is 7 degrees, and the output is 10 mW. The wavelength of light emitted from the red semiconductor laser chip 34 is 638 nm, the total angle of the spread of the beam in the lateral direction is 8 degrees, and the output is 10 mW. Here, the full width at half maximum (FWHM) is an angle at which the light intensity becomes half the intensity of the peak intensity.

The blue semiconductor laser chip 32, the green semiconductor laser chip 33 and the red semiconductor laser chip 34 are mounted in such a manner that the emission areas thereof are respectively matched with the entrance areas of the input optical waveguides 23 through 25 in the lateral direction and in the height direction with a gap vis-a-vis the input ends of the input optical waveguides 23 through 25 being 10 μm.

The structure of the optical multiplexing unit 27 is the same as that illustrated in FIG. 4A, and thus, an example thereof is described in reference to FIG. 4A, where the length of the optical coupling part 8₁ is 610 μm, the length of the optical coupling part 8₂ is 800 μm, and the length of the optical coupling part 8₃ is 610 μm. The optical waveguide 5₂ at the center of the optical waveguides is made linear, and thus, the number of portions at which an optical waveguide is bent is made smaller so that the entire size of the optical multiplexing unit can be made smaller. In this case, it is characteristic for the direction in which the laser is emitted to be approximately the same as the direction in which light progresses in the optical waveguide-type optical multiplexer. Here, the form of the input ends of the optical waveguides 23 through 25 may be altered to such a form as to be tapered in order to make it easier to take in light from each semiconductor laser.

Here, all the light beams emitted from the respective semiconductor lasers (32 through 34) are not guided into the core layer due to the difference in the shape between the light beams emitted from the semiconductor lasers (32 through 34) and the cores of the input optical waveguides 23 through 25 in the core layer, and partially leak into the clad portion made of the lower clad layer 22 and the upper clad layer so as to spread at a certain angle and propagate through the clad portion as illustrated in the figure. Concretely, light radiated from the blue semiconductor laser chip 32 propagates through the clad portion while spreading at an angle θ_{B}. Light radiated from the green semiconductor laser chip 33 propagates through the clad portion while spreading at an angle θ_{G}. In addition, light radiated from the red semiconductor laser chip 34 propagates through the clad portion while spreading at an angle θ_{R}.

The blue semiconductor laser chip 32, the green semiconductor laser chip 33, and the red semiconductor laser chip 34 are installed in such a manner that the output end 29 of the output optical waveguide 28 is not irradiated with all of the light radiated from the respective semiconductor laser chips, that is to say, the outer periphery of the entire radiated light does not overlap with the output end 29. Here, the blue semiconductor laser chip 32 and the green semiconductor laser chip 33 are arranged above the center line of the optical multiplexing unit 27, while the red semiconductor laser chip 34 is arranged beneath the center line.

As for the spread of the beam in the lateral direction in the clad portion after entering into the optical multiplexing unit 27, the total angle θ_{R} of the spread of the red laser beam in the lateral direction is 5.5 degrees, the total angle θ_{G} of the spread of the green laser beam in the lateral direction is 4.8 degrees, and the total angle θ_{B} of the spread of the blue laser beam in the lateral direction is 3.5 degrees. Here, the total angle of the spread of the beam in the lateral direction, that is to say, the full width at half maximum, of the clad mode light is the outer periphery of the radiated light, and thus, this outer periphery of the radiated light is prevented from overlapping with the output end 29.

Incidentally, the relationship between the point at which the light beam from each semiconductor laser reaches an end portion of the substrate and the location of the output end 29 of the output optical waveguide 28 is as follows, taking the length of the Si substrate 21 being 10 mm into consideration. In the case of the red laser beam, it is necessary for the output end 29 to be away from the center of the red laser beam by d_{R}=10 mm×tan (θ_{R}/2) or more. In the case of the green laser beam, it is necessary for the output end 29 to be away from the center of the green laser beam by d_{G}=10 mm×tan (θ_{G}/2) or more. In the case of the blue laser beam, it is necessary for the output end 29 to be away from the center of the blue laser beam by d_{B}=10 mm×tan (θ_{B}/2) or more. In reality, the relationship with the arrangement of the lasers is also involved, and as for the relationship between the point at which the light beam from each semiconductor laser reaches an end portion of the substrate and the location of the output end 29 of the output optical waveguide 28, the output end 29 is at 0.8 mm away from the center of the red laser beam in the case of the red laser beam, the output end 29 is at 0.8 mm away from the center of the green laser beam in the case of the green laser beam, and the output end 29 is at 1.3 mm away from the center of the blue laser beam in the case of the blue laser beam. Here, there is a gap vis-a-vis the end surface (this is set at 10 μm), and therefore, the size of a light beam in the input end is not a point and has a finite size; however, the size is so small as to be negligible as compared to the size of the optical multiplexing unit 27, and thus is regarded as a point for calculating d_{R}, d_{G} and d_{B}.

In this manner, the outer periphery of each radiated beam can be prevented from overlapping with the output end 29 so that the ratio of the clad mode light that has mixed with the multiplexed signal light and propagated through the clad portion can be suppressed to 1% or less. Here, the outer periphery is at the full width at half maximum; however, in the case where it is necessary to further reduce noise light in order to gain an image with high definition, the outer periphery may be at 1.5 times greater than the full width at half maximum, and furthermore, in the case where an image with higher definition is necessary, the outer periphery may be 2.5 times greater than the full width at half maximum, and thus, the greater the outer periphery is as compared to the full width at half maximum, the smaller the effects of noise light become.

In this case as well, in the same manner as in Example 2, LED chips may be used as the light sources instead of the semiconductor laser diode chips; in the same manner as in Example 3, a light shielding film may be provided in proximity to the output end 29 of the output optical waveguide 28; or the optical multiplexing unit may have the same structure as in Example 4 or 5.

### Example 15

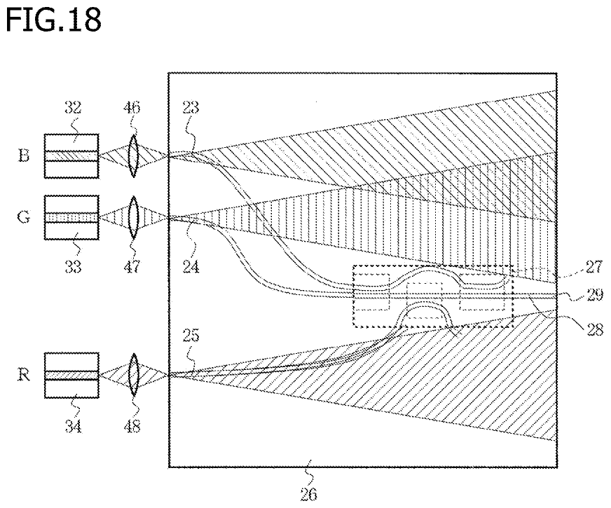

Next, the light source module in Example 15 of the present invention is described in reference to FIG. 18. The light source module in Example 15 is gained by providing lenses between the light sources and the input optical waveguides in the light source module in Example 14. FIG. 18 is a schematic diagram illustrating the configuration of the light source module in Example 15 of the present invention. As shown in FIG. 18, lenses 46 through 48 are provided vis-a-vis the blue semiconductor laser chip 32, the green semiconductor laser chip 33 and the red semiconductor laser chip 34.

In this case, microscopic sphere lenses having a focal distance of 0.54 mm and a sphere diameter of 1 mm are used as the lenses 46 through 48. Light beams that have been condensed by the microscopic sphere lenses are inputted into input optical waveguides 23 through 25. The condenser lenses are not limited to microscopic sphere lenses, and GRIN (gradient index type) lenses may be used.

In Example 15 as well, the outer periphery of each radiated beam is prevented from overlapping with the output end 29, and as a result, the ratio of the clad mode light that has mixed with the multiplexed signal light and propagated through the clad portion can be suppressed to 1% or less. In this case as well, in the same manner as in Example 2, LED chips may be used as the light sources instead of the semiconductor laser diode chips; in the same manner as in Example 3, a light shielding film may be provided in proximity to the output end 29 of the output optical waveguide 28; or the optical multiplexing unit may have the same structure as in Example 4 or 5.

### Example 16

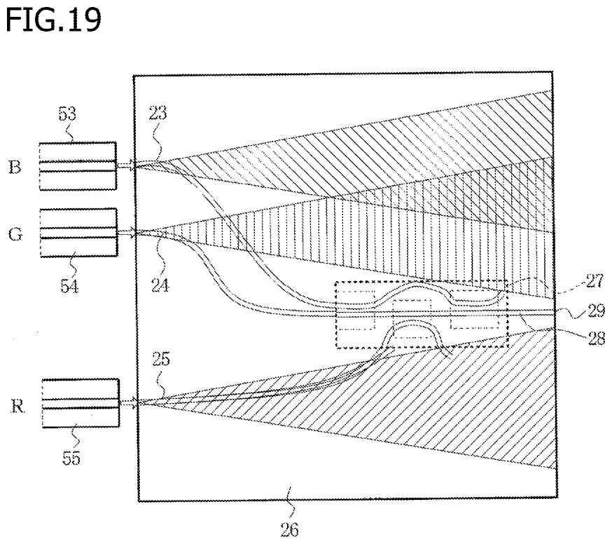

Next, the light source module in Example 16 of the present invention is described in reference to FIG. 19. The light source module in Example 16 is the same as in Example 14 except that optical fiber output ends are used for the light sources in place of the semiconductor lasers in the light source module in Example 14. As for the size of the Si substrate, the length is 10 mm and the width is 3.1 mm.

At the output ends of the optical fibers 53 through 55, the wavelength of light emitted as a red beam is 640 nm with the total angle of the spread of the beam in the lateral direction being 5 degrees and the output being 5 mW. The wavelength of light emitted as a green beam is 530 nm with the total angle of the spread of the beam in the lateral direction being 5 degrees and the output being 5 mW. The wavelength of light emitted as a blue beam is 450 nm with the total angle of the spread of the beam in the lateral direction being 5 degrees and the output being 5 mW.

After the respective beams have entered into the optical multiplexer, the total angle θ_{R} of the spread of the red beam in the lateral direction, the total angle θ_{G} of the spread of the green beam in the lateral direction and the total angle θ_{B} of the spread of the blue beam in the lateral direction are all 3.5 degrees in the clad portion. Here, the gap between the input end of the input optical waveguide 23 and the output end 29 of the output optical waveguide 28 is 1.3 mm in the arrangement, the gap between the input end of the input optical waveguide 24 and the output end 29 of the output optical waveguide 28 is 0.8 mm in the arrangement, and the gap between the input end of the input optical waveguide 25 and the output end 29 of the output optical waveguide 28 is 0.8 mm in the arrangement.

In Example 16 as well, the outer periphery of each radiated beam is prevented from overlapping with the output end 29, and as a result, the ratio of the clad mode light that has mixed with the multiplexed signal light and propagated through the clad portion can be suppressed to 1% or less. In this case as well, in the same manner as in Example 2, LED chips may be used as the light sources instead of the semiconductor laser diode chips; in the same manner as in Example 3, a light shielding film may be provided in proximity to the output end 29 of the output optical waveguide 28; the optical multiplexing unit may have the same structure as in Example 4 or 5; or condenser lenses may be provided between the optical fibers 53 through 55 and the input optical waveguides 23 through 25.

### Example 17

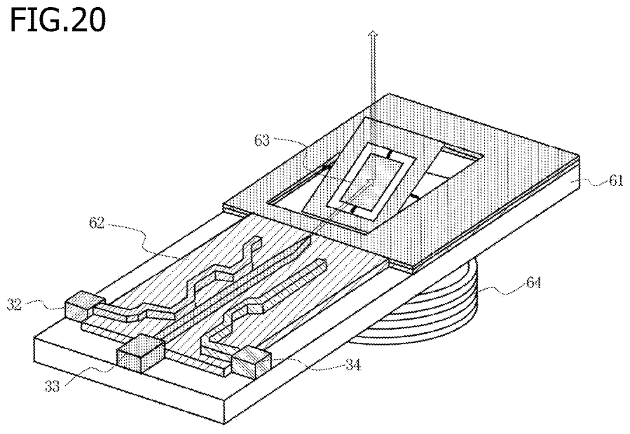

Next, the two-dimensional optical scanning device in Example 17 of the present invention is described in reference to FIG. 20 since the basic configuration in Example 17 is the same as that of the two-dimensional optical scanning device illustrated in FIG. 20 with only a difference in the configuration of the optical multiplexer. The two-dimensional optical scanning device in Example 17 of the present invention is provided by replacing the optical multiplexer 62 in the two-dimensional optical scanning device in FIG. 20 with the above-described optical multiplexer in Example 1. Here, this optical multiplexer may be replaced with any of the optical multiplexers in Examples 2 through 13. Furthermore, as illustrated in FIG. 18 or 19, lenses may be provided, or the light sources may be replaced with optical fibers.

### Example 18

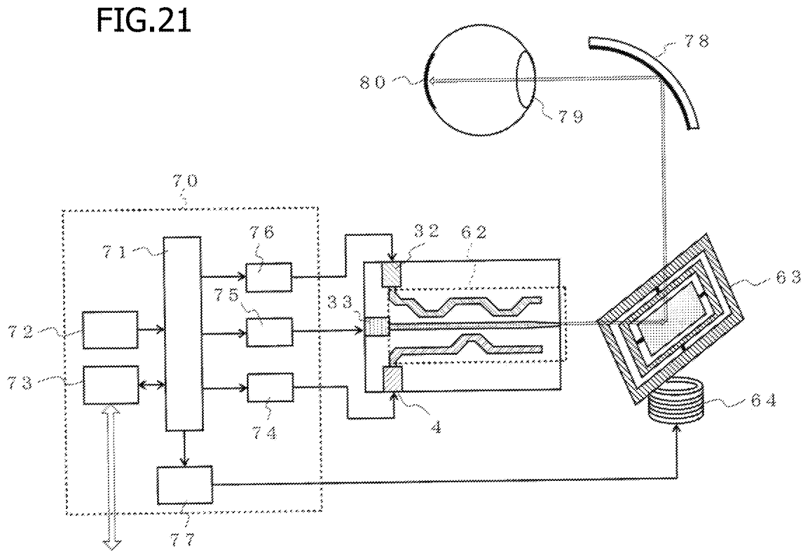

Next, the image formation device in Example 18 of the present invention is described in reference to FIG. 21 since the basic configuration in Example 18 is the same as that of the image formation device illustrated in FIG. 21 with only a difference in the configuration of the optical multiplexer. The image formation device in Example 18 of the present invention is provided by replacing the optical multiplexer 62 in the image formation device in FIG. 21 with the above-described optical multiplexer in Example 1. Here, this optical multiplexer may be replaced with any of the optical multiplexers in Examples 2 through 13. Furthermore, as illustrated in FIG. 18 or 19, lenses may be provided, or the light sources may be replaced with optical fibers.

In this image formation device, in the same manner as in the prior art, a control unit 70 has a sub-control unit 71, an operation unit 72, an external interface (I/F) 73, an R laser driver 74, a G laser driver 75, a B laser driver 76 and a two-dimensional scanning driver 77. The sub-control unit 71 is formed of a microcomputer that includes a CPU, a ROM, a RAM and the like. The sub-control unit 71 generates an R signal, a G signal, a B signal, a horizontal signal and a vertical signal that become elements for synthesizing an image on the basis of the image data supplied from an external apparatus such as a PC via the external I/F 73. The sub-control unit 71 transmits the R signal to the R laser driver 74, the G signal to the G laser driver 75, and the b signal to the B laser driver 76, respectively. In addition, the sub-control unit 71 transmits the horizontal signal and the vertical signal to the two-dimensional scanning driver 77, and controls the current to be applied to the electromagnetic coil 64 so as to control the operation of the movable mirror unit 63.

The R laser driver 74 drives the red semiconductor laser chip 34 so that a red laser beam of which the optical quantity corresponds to the R signal from the sub-control unit 71 is generated. The G laser driver 75 drives the green semiconductor laser chip 33 so that a green laser beam of which the optical quantity corresponds to the G signal from the sub-control unit 71. The B laser driver 76 drives the blue semiconductor laser chip 32 so that a blue laser beam of which the optical quantity corresponds to the B signal from the sub-control unit 71 is generated. It becomes possible to synthesize a laser beam having a desired color by adjusting the intensity ratio between the laser beams of the respective colors.

The respective laser beams generated in the blue semiconductor laser chip 32, the green semiconductor laser chip 33 and the red semiconductor laser chip 34 are multiplexed in the optical multiplexing unit 27 in the optical multiplexer, and after that reflected from the movable mirror unit 63 for two-dimensional scanning. An image is formed on a retina 80 as a result of scanning with the multiplexed laser beam that has been reflected from a concave reflection mirror 78 and passed through a pupil 79.

### REFERENCE SIGNS LIST

1 substrate
2 lower clad layer
3₁ through 3₃ core layer
4 upper clad layer
5₁ through 5₄ input optical waveguide
5₅ optical waveguide
6 clad portion
7 optical multiplexing unit
8₁ through 8₆ coupling unit
9 output optical waveguide
10, 10₁ through 10₃ input end
11 output end
12₁ through 12₃ light source
13₁ through 13₃ active layer
14, 14₁ through 14₃ clad mode light
15 clad mode light distribution
16 multiplexed output light distribution
21 Si substrate
22 SiO₂ film
23 through 25, 25₁, 25₂ input optical waveguide
26 upper clad layer
27, 36, 44 optical multiplexer
28, 45 output optical waveguide
29 output end
32 blue semiconductor laser chip
33 green semiconductor laser chip
34, 34₁, 34₂ red semiconductor laser chip
35 light shielding film
37 through 39 upper clad layer
40 through 42 lower clad layer
46 through 48 lens
50 multiplexed output light
51 clad mode light
52 noise light
53 through 55 optical fiber
61 substrate
62 optical multiplexer
63 movable mirror unit
64 electromagnetic coil
70 control unit
71 sub-control unit
72 operation unit
73 external interface (I/F)
74 R laser driver
75 G laser driver
76 B laser driver
77 two-dimensional scanning driver
78 concave reflection mirror
79 pupil
80 retina

1. An optical multiplexer, comprising:
a plurality of input optical waveguides for individually guiding light beams from a plurality of light sources;
an optical multiplexing unit for multiplexing a plurality of light beams from the input optical waveguides; and
an output optical waveguide for outputting multiplexed light that has been multiplexed in the optical multiplexing unit, wherein
light that is in or below the range of 2.5 times greater than the full width at half maximum of the light intensity distribution of a light beam that has not entered into the input optical waveguide from among the respective light beams that have entered into the input ends of the plurality of input optical waveguides does not overlap with the multiplexed light outputted from the output optical waveguide in the output end of the output optical waveguide.

2. The optical multiplexer according to claim 1, wherein light that is in or below the range of 1.5 times greater than the full width at half maximum of the light intensity distribution of a light beam that has not entered into the input optical waveguide from among the respective light beams that have entered into the input ends of the plurality of input optical waveguides does not overlap with the multiplexed light outputted from the output optical waveguide in the output end of the output optical waveguide.

3. The optical multiplexer according to claim 1, wherein light that is in the range of the full width at half maximum of the light intensity distribution of a light beam that has not entered into an input optical waveguide from among the respective light beams that have entered into the input ends of the plurality of input optical waveguides does not overlap with the multiplexed light outputted from the output optical waveguide at the output end of the output optical waveguide.

4. The optical multiplexer according to claim 1, wherein the light intensity distribution at the output end of any of the respective input optical waveguides is a light intensity distribution of the spread in the lateral direction of a light beam that has propagated through a clad portion.

5. The optical multiplexer according to claim 1, wherein the plurality of light sources emits light having different wavelengths.

6. The optical multiplexer according to claim 1, wherein at least two light sources from among the plurality of light sources emit light having the same wavelength.

7. The optical multiplexer according to claim 5, wherein the optical multiplexer multiplexes light of at least three primary colors, red light, blue light and green light.

8. The optical multiplexer according to claim 7, wherein the optical multiplexer has an optical waveguide for guiding red light, an optical waveguide for guiding blue light and an optical waveguide for guiding green light, and the optical waveguide that is arranged at the center from among the three optical waveguides is an optical waveguide in linear form.

9. The optical multiplexer according to claim 7, wherein the optical multiplexer has: an optical waveguide in linear form for guiding green light; an optical waveguide for guiding blue light that optically couples with the optical waveguide for guiding green light through two optical coupling parts; and an optical waveguide for guiding red light that optically couples with the optical waveguide for guiding green light through a portion between the two optical coupling parts, and the optical waveguide for guiding green light is connected to the output optical waveguide.

10. The optical multiplexer according to claim 7, wherein the optical multiplexer has: an optical waveguide in linear form for guiding red light; an optical waveguide for guiding blue light that optically couples with the optical waveguide for guiding red light; and an optical waveguide for guiding green light that optically couples with the optical waveguide for guiding red light, and the optical waveguide for guiding red light is connected to the output optical waveguide.

11. The optical multiplexer according to claim 9, wherein
axes along which light beams from the plurality of light sources are directed in proximity to the input ends of the plurality of input optical waveguides lie in locations that are away from the optical axis of the optical waveguide in linear form in the optical multiplexing unit.

12. The optical multiplexer according to claim 9, wherein
the output end of the output optical waveguide is arranged in the location that is different from the optical axis of the optical waveguide in linear form in the optical multiplexing unit.

13. The optical multiplexer according to claim 12, wherein
the output end of the output optical waveguide is arranged in the direction of 85° to 95° relative to the optical axis of the optical waveguide in linear form in the optical multiplexing unit.

14. The optical multiplexer according to claim 9, wherein
axes along which light beams from the plurality of light sources are directed in proximity to the input ends of the plurality of input optical waveguides extends in the direction of 85° to 95° relative to the optical axis of the optical waveguide in linear form in the optical multiplexing unit.

15. The optical multiplexer according to claim 14, wherein
axes along which light beams from the plurality of light sources are directed in proximity to the input ends of the plurality of input optical waveguides are arranged along one side of a substrate that forms an angle of 85° to 95° with the optical axis of the optical waveguide in linear form in the optical multiplexing unit on the substrate on which the optical multiplexing unit is formed.

16. The optical multiplexer according to claim 14, wherein
axis along which at least one light beam from the plurality of light sources is directed in proximity to one input ends of the plurality of input optical waveguides is arranged in proximity to a first side of a substrate that forms an angle of 85° to 95° with the optical axis of the optical waveguide in linear form in the optical multiplexing unit on the substrate on which the optical multiplexing unit is formed, and axis along which the remaining light beams from the plurality of light sources is directed in proximity to input ends of the plurality of input optical waveguides is arranged in proximity to a second side, which faces the first side.

17. The optical multiplexer according to claim 1, wherein
the input optical waveguides, the respective optical waveguides in the optical multiplexing unit and the output optical waveguide comprise:
a common lower clad layer;
a core layer provided on top of the lower clad layer; and
a common upper clad layer that covers the core layer.

18. The optical multiplexer according to claim 4, wherein
the input optical waveguides comprise:
an individual lower clad in a lower clad layer;
a core layer provided on top of the lower clad layer; and
an individual upper clad layer that covers each core layer,
the respective optical waveguides in the optical multiplexing unit and the output optical waveguide comprise:
a common lower clad layer;
a core in a core layer provided on top of the common lower clad layer; and
a common upper clad layer that covers the core layer, and
the light intensity distribution at the output end of each input optical waveguide is the light intensity distribution of the spread in the lateral direction of a light beam that has propagated through the clad portion from the connection portion between the input optical wave guide and the optical multiplexing unit.

19. The optical multiplexer according to claim 1, wherein
the input optical waveguides, the respective optical waveguides in the optical multiplexing unit and the output optical waveguide comprise:
a common lower clad layer;
a core layer provided on top of the lower clad layer; and
an individual upper clad layer that covers the core layer.

20. The optical multiplexer according to claim 1, wherein a light shielding film for reflecting or absorbing light that is in or below the range of 2.5 times greater than the full width at half maximum of the light intensity distribution of a light beam that has not been inputted into an input optical waveguide from among the respective light beams that have been inputted into the input ends of the plurality of input optical waveguides is provided at a location where the multiplexed light from the output end of the output optical waveguide is not shielded.

21. A light source module, comprising:
the optical multiplexer according to claim 1; and
a plurality of light sources for emitting light beams into the optical multiplexer.

22. The light source module according to claim 21, wherein a lens is provided between the plurality of light sources and a plurality of input optical waveguides in the optical multiplexer.

23. The light source module according to claim 21, wherein the plurality of light sources is a source of light emitted from a plurality of optical fibers.

24. A two-dimensional optical scanning device, comprising:
the light source module according to claim 21; and
a two-dimensional optical scanning mirror device for two-dimensional scanning with multiplexed light from the light source module.

25. An image projection device, comprising:
the two-dimensional optical scanning device according to claim 24; and
an image formation unit for projecting onto a projection surface multiplexed light scanned by the two-dimensional optical scanning mirror device.
